(19) United States
(12) Patent Application Publication
(10) Pub. No.: US 2025/0351643 A1
(43) Pub. Date: Nov. 13, 2025

(54) DISPLAY DEVICE AND METHOD OF MANUFACTURING THE SAME

(71) Applicant: Samsung Display Co., LTD., Yongin-si (KR)

(72) Inventor: Sang Ho PARK, Yongin-si (KR)

(73) Assignee: Samsung Display Co., LTD., Yongin-si (KR)

(21) Appl. No.: 19/077,693

(22) Filed: Mar. 12, 2025

(30) Foreign Application Priority Data
May 9, 2024 (KR) 10-2024-0061310

(51) Int. Cl. H10H 29/34; H10H 29/01; H10H 29/80

(52) U.S. Cl. CPC H10H 29/34; H10H 29/012; H10H 29/8321

(57) ABSTRACT

A display device includes pixels including light-emitting elements disposed in each emission area. Each of the pixels includes at least one array including the light-emitting elements and disposed in the emission area, and a number of the light-emitting elements disposed in each of arrays of the pixels is greater than aa minimum number of the light-emitting elements in the each of the arrays having a normal distribution or Poisson distribution.

### CROSS-REFERENCE TO RELATED APPLICATION(S)

This application claims priority to and benefits of Korean Patent Application No. 10-2024-0061310 under 35 U.S.C. 119, filed on May 9, 2024, in the Korean Intellectual Property Office (KIPO), the entire contents of which are incorporated herein by reference.

### BACKGROUND

### 1. Technical Field

The disclosure relates to a display device and a method of manufacturing the same, and an electronic device for providing an image.

### 2. Description of the Related Art

A display device is a device that displays an image, and its importance is gradually increasing with the development of multimedia. Accordingly, various types of display devices, including a light-emitting display device, are being developed. The light-emitting display device includes pixels including light-emitting elements.

### SUMMARY

Aspects of the disclosure provide a display device capable of reducing deterioration of pixels including light-emitting elements and a method of manufacturing the same, and an electronic device for providing an image.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device may include pixels including light-emitting elements disposed in each emission area. Each of the pixels may include at least one array including the light-emitting elements and disposed in the emission area, and a number of the light-emitting elements disposed in each of arrays of the pixels may be greater than a minimum number of the light-emitting elements in the each of the arrays according to a normal distribution or Poisson distribution.

In an embodiment, the number of the light-emitting elements disposed in the each of the arrays of the pixels may be greater than or equal to two.

In an embodiment, the light-emitting elements disposed in the each of the arrays of the pixels may be connected in parallel to each other.

In an embodiment, the display device may further include a display area where the pixels are disposed. The number of the light-emitting elements disposed in each of entire arrays of the pixels in the display area may be greater than the minimum number of the light-emitting elements according to the normal distribution or Poisson distribution disposed in the each of the entire arrays.

In an embodiment, the number of the light-emitting elements disposed in each of the entire arrays may be greater than or equal to two.

In an embodiment, a distribution of the number of the light-emitting elements disposed in the each of the arrays of the pixels may have an asymmetric shape with respect to a mode.

In an embodiment, the each of the pixels may further include a first pixel electrode electrically connected to ends of the light-emitting elements, and a second pixel electrode electrically connected to another ends of the light-emitting elements.

In an embodiment, the light-emitting elements of the each of the pixels may include effective light-emitting elements connected between the first pixel electrode and the second pixel electrode.

In an embodiment, the each of the pixels may include at least two arrays, and the number of the light-emitting elements disposed in each of the at least two arrays may be greater than or equal to two.

In an embodiment, each of a width and a length of the light-emitting elements may be less than or equal to about 100 μm.

In an embodiment, the each of the pixels may further include at least one pair of alignment electrodes disposed adjacent to the light-emitting elements.

In an embodiment, the light-emitting elements of the each of the pixels may be arranged between the at least one pair of alignment electrodes.

According to an embodiment of the disclosure, a method of manufacturing a display device may include preparing light-emitting elements, supplying the light-emitting elements to emission areas of pixels, aligning the light-emitting elements in arrays disposed in the emission areas, counting the light-emitting elements disposed in each of the arrays, and connecting the light-emitting elements between a first pixel electrode and a second pixel electrode of each of the pixels. After the counting of the light-emitting elements, the light-emitting elements may be additionally supplied to at least one array supplied with a number of the light-emitting elements less than a reference number, among the arrays.

In an embodiment, in case that the number of the light-emitting elements disposed in the at least one array among the arrays is less than the reference number, the light-emitting elements may be additionally supplied to and aligned in the at least one array until the number of the light-emitting elements disposed in the at least one array is greater than or equal to the reference number.

In an embodiment, the reference number may be greater than or equal to two.

In an embodiment, the preparing of the light-emitting elements may include preparing a light-emitting element ink including the light-emitting elements.

In an embodiment, the supplying of the light-emitting elements to the emission areas may include supplying the light-emitting element ink to the emission areas by an inkjet printing method.

In an embodiment, the aligning of the light-emitting elements in the arrays may include applying an alignment signal to alignment electrodes disposed in the emission areas.

In an embodiment, the connecting of the light-emitting elements between the first pixel electrode and the second pixel electrode of the each of the pixels may include forming a plurality of pixel electrodes including the first pixel electrode and the second pixel electrode on ends of the light-emitting elements.

In an embodiment, the connecting of the light-emitting elements between the first pixel electrode and the second pixel electrode of the each of the pixels may include connecting the light-emitting elements disposed in the each of the arrays in parallel.

According to an embodiment of the disclosure, an electronic device for providing an image may include a display device including pixels. The pixels may include light-emitting elements disposed in each emission area. Each of the pixels may include at least one array including the light-emitting elements and disposed in the emission area, and a number of the light-emitting elements disposed in each of arrays of the pixels may be greater than a minimum number of the light-emitting elements in the each of the arrays according to a normal distribution or Poisson distribution.

Each of the pixels of the display device according to embodiments may include at least one array including light-emitting elements. The light-emitting elements of which number is greater than a reference number may be disposed in each array. In one embodiment, the reference number may be greater than the minimum number of the light-emitting elements in each array according to normal distribution or Poisson distribution. In accordance with the display device and the method of manufacturing the same according to embodiments, deterioration of light-emitting elements and pixels including the same may be improved, and the image quality of the display device may be improved.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a plan view illustrating a display device according to one embodiment;

FIG. 2 is a plan view showing the unit pixel area according to one embodiment;

FIG. 3 is a plan view showing the unit pixel area according to one embodiment;

FIG. 4 is a schematic diagram of an equivalent circuit of a pixel according to one embodiment;

FIG. 5 is a schematic diagram of an equivalent circuit of the pixel according to one embodiment;

FIG. 6 is a perspective view showing a light-emitting element according to one embodiment;

FIG. 7 is a plan view showing the unit pixel area according to one embodiment;

FIG. 8 is a plan view showing a pixel area according to one embodiment;

FIG. 9 is a schematic cross-sectional view illustrating a display device according to one embodiment;

FIG. 10 is a flowchart illustrating a method of manufacturing the display device according to one embodiment;

FIG. 11 is a graph showing distribution of the light-emitting elements according to one embodiment;

FIG. 12 is a graph showing changes in efficiency due to deterioration of the light-emitting elements;

FIG. 13 is a graph showing changes in luminance maintenance rate due to the deterioration of the light-emitting elements;

FIGS. 14 to 16 are graphs showing changes in luminance for each grayscale of the pixels including the light-emitting elements having different reliabilities; and

FIGS. 17 to 19 are graphs showing changes in ratio of non-emission recombination coefficients and changes in luminance maintenance rate of the light-emitting elements having different reliabilities with respect to time.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Features of each of various embodiments of the disclosure may be partially or entirely combined with each other and may technically variously interwork with each other, and respective embodiments may be implemented independently of each other or may be implemented together in association with each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

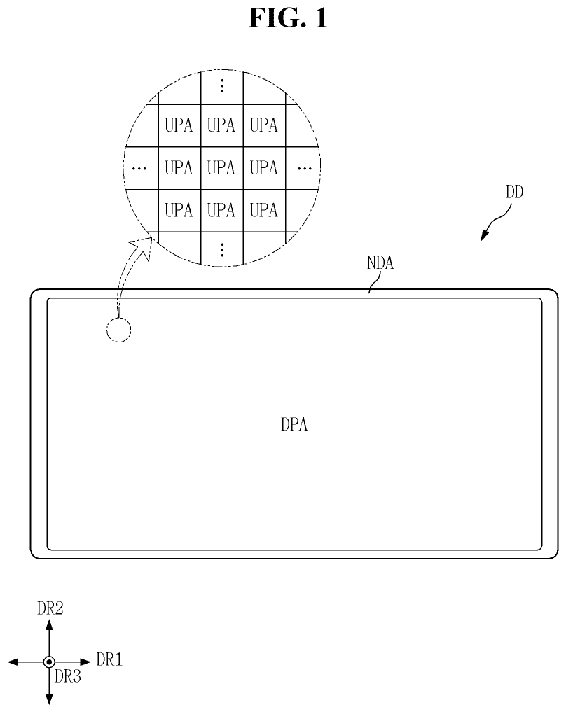

FIG. 1 is a plan view illustrating a display device DD according to one embodiment.

Referring to FIG. 1, a display device DD which is a device that displays an image, may be applied to any electronic device that provides a display screen. Examples of the display device DD may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device DD may include a display panel which provides an image. In one embodiment, the display device DD may be a light-emitting display device, and may include a display panel including light-emitting elements. FIG. 1 shows a schematic shape of the display device DD with respect to the display panel.

In FIG. 1, a first direction DR1, a second direction DR2, and a third direction DR3 are indicated. The first direction DR1 may be a horizontal direction or a row direction of the display device DD, and the second direction DR2 may be a direction intersecting the first direction DR1, for example, a vertical direction or a column direction of the display device DD. The third direction DR3 may be a direction intersecting the first direction DR1 and the second direction DR2 and may be, for example, a thickness direction or a height direction of the display device DD.

The display device DD may have various shapes. For example, the display device DD may have a horizontally long rectangular shape, a vertically long rectangular shape, a square shape, a quadrilateral shape with rounded corners where horizontal sides and vertical sides meet, another non-quadrilateral polygonal shape, a circular shape, an elliptical shape, or another shape in a plan view.

The display device DD may include a display area DPA where an image is displayed. In one embodiment, the shape of the display area DPA may be similar to the overall shape of the display device DD. FIG. 1 shows an embodiment in which the display device DD and the display area DPA have a horizontally long rectangular shape with rounded corners.

The display device DD may include the display area DPA and a non-display area NDA. The display area DPA may be an area in which an image is displayed, and the non-display area NDA may be an area other than the display area DPA.

The display area DPA may include unit pixel areas UPA where unit pixels are disposed. In each unit pixel area UPA, each unit pixel including at least two pixels may be disposed. For example, a unit pixel including at least two pixels that emit light of different colors may be disposed in each unit pixel area UPA.

The non-display area NDA may be disposed adjacent to the display area DPA. The non-display area NDA may completely or partially surround the display area DPA. Wires included in the display device DD may be disposed in the non-display area NDA. For example, power lines and signal lines connected to pixels may be disposed in the non-display area NDA. In one embodiment, pads (for example, power pads and signal pads electrically connected to a built-in driving circuit or pixels through respective wires) connected to wires of the display panel, a driving circuit (for example, a gate driving circuit including a scan driving circuit), or a circuit board (for example, a printed circuit board on which a data driving circuit and the like are mounted) may be further disposed in the non-display area NDA.

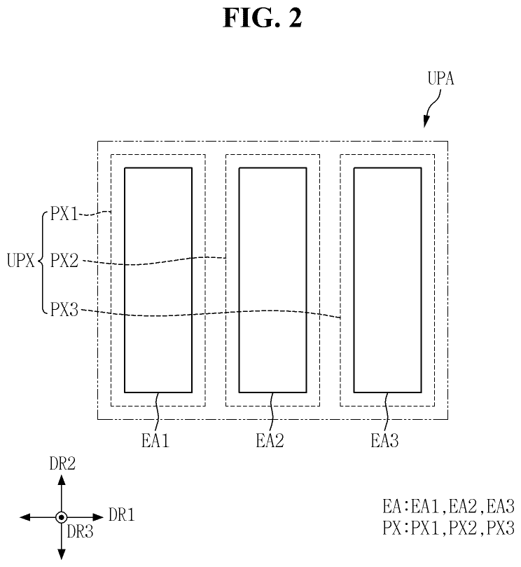

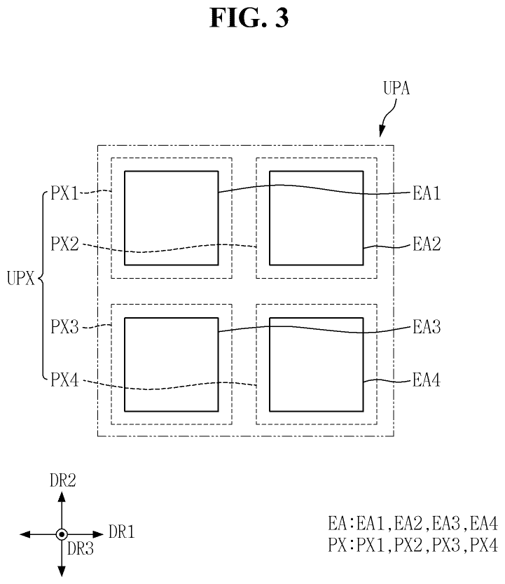

FIG. 2 is a plan view showing the unit pixel area UPA according to one embodiment. FIG. 3 is a plan view showing the unit pixel area UPA according to one embodiment. For example, FIGS. 2 and 3 show different embodiments of the unit pixel UPX that may be disposed in the unit pixel area UPA of FIG. 1.

Referring to FIGS. 2 and 3, each unit pixel UPX may be disposed in each unit pixel area UPA. The unit pixel UPX may include at least two pixels PX that emit light of different colors. Each pixel PX may include at least one emission area EA. At least one light-emitting element may be disposed in each emission area EA. For example, multiple light-emitting elements may be disposed in each emission area EA.

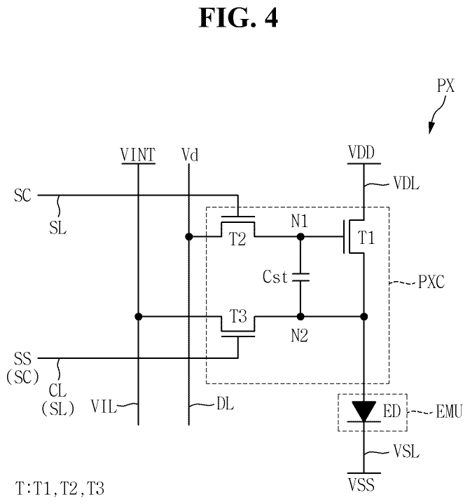

Although FIGS. 2 and 3 illustrate an embodiment in which the unit pixel area UPA has a quadrilateral shape, the disclosure is not limited thereto, and the shape of the unit pixel area UPA may be variously changed depending on embodiments. Although FIGS. 2 and 3 illustrate embodiments in which three pixels PX and four pixels PX are disposed in the unit pixel area UPA, respectively, the disclosure is not limited thereto, and the number or type of the pixels PX forming each unit pixel UPX may be variously changed depending on embodiments. Further, the shape, size, ratio (for example, area ratio), or arrangement structure of the emission areas EA of the pixels PX disposed in the unit pixel area UPA is not limited to the embodiments illustrated in FIGS. 2 and 4, and may be variously changed depending on embodiments.

In one embodiment, the unit pixel UPX may include a first pixel PX1, a second pixel PX2, and a third pixel PX3 as shown in FIG. 2. The first pixel PX1, the second pixel PX2, and the third pixel PX3 may include a first emission area EA1, a second emission area EA2, and a third emission area EA3, respectively. In one embodiment, the first emission area EA1, the second emission area EA2, and the third emission area EA3 may be sequentially arranged in the first direction DR1, but the disclosure is not limited thereto. The sizes of the first emission area EA1, the second emission area EA2, and the third emission area EA3 may be substantially the same, or the sizes of at least two emission areas EA of the first emission area EA1, the second emission area EA2, and the third emission area EA3 may be different from each other in a plan view.

The first pixel PX1, the second pixel PX2, and the third pixel PX3 may emit light of a first color, light of a second color, and light of a third color, respectively. In one embodiment, the light of the first color, the light of the second color, and the light of the third color may be red light, green light, and blue light, respectively, but the disclosure is not limited thereto.

In one embodiment, the first pixel PX1, the second pixel PX2, and the third pixel PX3 may include a first light-emitting element (for example, a red light-emitting element) that emits light of a first color, a second light-emitting element (for example, a green light-emitting element) that emits light of a second color, and a third light-emitting element (for example, a blue light-emitting element) that emits light of a third color, respectively. In another embodiment, the first pixel PX1, the second pixel PX2, and the third pixel PX3 may include light-emitting elements (for example, blue light-emitting elements or white light-emitting elements) that emit light of a same color, and at least one of a color filter or a wavelength conversion layer (for example, a wavelength conversion layer including quantum dots) for converting a color or wavelength of light emitted from the light-emitting element of the corresponding pixel PX into another color or wavelength may be further disposed in the emission area EA of at least one pixel PX of the first pixel PX1, the second pixel PX2, and the third pixel PX3.

In one embodiment, the unit pixel UPX may include the first pixel PX1, the second pixel PX2, the third pixel PX3, and a fourth pixel PX4 as shown in FIG. 3. The first pixel PX1, the second pixel PX2, the third pixel PX3, and the fourth pixel PX4 may include the first emission area EA1, the second emission area EA2, the third emission area EA3, and the fourth emission area EA4, respectively. In one embodiment, the first emission area EA1, the second emission area EA2, the third emission area EA3, and the fourth emission area EA4 may be arranged in a matrix form of 2 rows and 2 columns in the first direction DR1 and the second direction DR2, but the disclosure is not limited thereto. The sizes of the first emission area EA1, the second emission area EA2, the third emission area EA3, and the fourth emission area EA4 may be substantially the same, or the sizes of at least two emission areas EA among the first emission area EA1, the second emission area EA2, the third emission area EA3, and the fourth emission area EA4 may be different from each other in a plan view.

The first pixel PX1, the second pixel PX2, the third pixel PX3, and the fourth pixel PX4 may emit light of the first color, light of the second color, light of the third color, and light of a fourth color, respectively. In one embodiment, the light of the first color, the light of the second color, the light of the third color, and the light of the fourth color may be red light, green light, blue light, and white light, respectively, but the disclosure is not limited thereto. In another embodiment, among the first pixel PX1, the second pixel PX2, the third pixel PX3, and the fourth pixel PX4, two pixels PX may emit light of a same color (for example, red light, green light or blue light).

In one embodiment, the first pixel PX1, the second pixel PX2, the third pixel PX3, and the fourth pixel PX4 may include light-emitting elements that emit light of different colors. In another embodiment, at least two pixels PX of the first pixel PX1, the second pixel PX2, the third pixel PX3, and the fourth pixel PX4 may include light-emitting elements that emit light of a same color. Each of the first pixel PX1, the second pixel PX2, the third pixel PX3, and the fourth pixel PX4 may include the wavelength conversion layer for converting the color of light emitted from the light-emitting element of the corresponding pixel PX or may not include the wavelength conversion layer. In one embodiment, the color filter corresponding to the color of light to be emitted from each pixel PX may be disposed in the emission area EA of each of the first pixel PX1, the second pixel PX2, the third pixel PX3, and the fourth pixel PX4.

In addition to the embodiments illustrated in FIGS. 2 and 3, the shape, structure, or components of the unit pixel UPX disposed in each unit pixel area UPA may be variously changed depending on embodiments. Further, the shape or type of the pixels PX included in each unit pixel UPX may be variously changed depending on embodiments.

FIG. 4 is a schematic diagram of an equivalent circuit of the pixel PX according to one embodiment. For example, FIG. 4 shows a pixel PX of the light-emitting display device including a light-emitting element ED. In one embodiment, the pixel PX of FIG. 4 may be a pixel PX disposed in the unit pixel UPX of FIG. 2 or FIG. 3. For example, the pixel PX of FIG. 4 may be the first pixel PX1, the second pixel PX2, the third pixel PX3, or the fourth pixel PX4 of FIG. 2 or FIG. 3. In one embodiment, the pixels PX of the display device DD may have structures that are substantially the same or similar to each other.

Referring to FIG. 4, the pixel PX may include a light-emitting unit EMU including at least one light-emitting element ED, and a pixel circuit PXC connected to the light-emitting unit EMU. In one embodiment, the pixel PX may be connected to a scan line SL that transmits a scan signal SC, a control line CL that transmits a control signal SS (for example, a sensing control signal or an initialization control signal), and a data line DL that transmits a data signal Vd. Although FIG. 4 illustrates an embodiment in which the scan line SL and the control line CL are separated from each other, the disclosure is not limited thereto. For example, the control line CL may be a part of the scan line SL and branched from the scan line SL, and the control signal SS may be the scan signal SC. Further, the pixel PX may be connected to a first power line VDL that transmits a driving voltage VDD (also referred to as “first pixel voltage”), and a second power line VSL that transmits a common voltage VSS (also referred to as “second pixel voltage”). The voltage level of the common voltage VSS may be lower than the voltage level of the driving voltage VDD. In one embodiment, the pixel PX may be further connected to an initialization power line VIL (or a sensing line) that transmits an initialization voltage VINT (also referred to as “third pixel power voltage”).

The pixel circuit PXC may be connected between the first power line VDL and the light-emitting unit EMU. In one embodiment, the pixel circuit PXC may be further connected to the scan line SL, the control line CL, the data line DL, and the initialization power line VIL. The pixel circuit PXC may control emission of the light-emitting unit EMU in response to driving signals supplied from a driving circuit (for example, a gate driving circuit and a data driving circuit). For example, the pixel circuit PXC may supply a driving current to the light-emitting unit EMU in response to the scan signal SS and the control signal CS supplied through the scan line SL and the control line CL, and the data signal Vd supplied through the data line DL.

The pixel circuit PXC may include transistors T and a capacitor Cst. In one embodiment, the pixel circuit PXC may include a first transistor T1, a second transistor T2, a third transistor T3, and the capacitor Cst. Although FIG. 4 shows an embodiment in which all the transistors T are N-type transistors, the types of the transistors T are not limited thereto. For example, at least one transistor T may be formed as a P-type transistor. Further, the structure or driving method of the pixel circuit PXC is not limited to the embodiment of FIG. 4, and may be variously changed depending on embodiments.

The first transistor T1 may be a driving transistor of the pixel PX, and a magnitude of drain-source current (e.g., driving current) may be determined depending on the gate-source voltage. The second and third transistors T2 and T3 may be switching transistors that are turned on or turned off depending on respective gate-source voltages. Depending on the type (for example, P-type or N-type transistor) and/or operating conditions of each of the transistors T, the first electrode of each of the transistors T may be a drain electrode (or a drain region) or a source electrode (or a source region), and the second electrode of each of the transistors T may be an electrode different from the first electrode. For example, in case that the first electrode is a drain electrode, the second electrode may be a source electrode.

In one embodiment, the transistors T may be located in each pixel area, and may be oxide transistors (also referred to as “oxide semiconductor transistors”) including an oxide semiconductor. For example, an active layer of each of the first, second, and third transistors T1, T2, and T3 may include an oxide semiconductor. However, the disclosure is not limited thereto. In another embodiment, at least one transistor T may be formed of a semiconductor material (for example, amorphous silicon or polysilicon) other than an oxide semiconductor.

The first transistor T1 may include a gate electrode connected to a first node N1, a first electrode (for example, a drain electrode) connected to the first power line VDL, and a second electrode (for example, a source electrode) connected to a second node N2. The second node N2 may be a node at which the pixel circuit PXC and the light-emitting unit EMU are connected. The first transistor T1 may control the driving current of the pixel PX in response to the data signal Vd transmitted to the first node N1.

The second transistor T2 may include a gate electrode connected to the scan line SL, a first electrode connected to the data line DL, and a second electrode connected to the first node N1. The second transistor T2 may be turned on by the scan signal SC of the gate-on voltage applied to the scan line SL to connect the data line DL to the first node N1. Accordingly, the data signal Vd applied to the data line DL may be transmitted to the first node N1.

The third transistor T3 may include a gate electrode connected to the control line CL (or the scan line SL), a first electrode connected to the second node N2, and a second electrode connected to the initialization voltage line VIL. The third transistor T3 may be turned on by the control signal SS (or the scan signal SC) of the gate-on voltage applied to the control line CL (or the scan line SL) to connect the initialization voltage line VIL to the second node N2.

The capacitor Cst may be connected between the first node N1 and the second node N2. The capacitor Cst may store a voltage (for example, a difference voltage between the gate voltage and the source voltage of the first transistor T1) corresponding to the data signal Vd (for example, data voltage) transmitted to the first node N1.

The light-emitting unit EMU may be connected between the pixel circuit PXC and the second power line VSL. The light-emitting unit EMU may include the light-emitting element ED that emits light in response to the driving current supplied from the pixel circuit PXC as a light source of the pixel PX. The light-emitting element ED may be an organic light-emitting diode or an inorganic light-emitting diode. In one embodiment, the light-emitting element ED may be an ultra-small inorganic light-emitting diode (for example, a micro light-emitting diode (micro LED) or a nano LED) having a micrometer or nanometer size, but the disclosure is not limited thereto.

The light-emitting unit EMU may include a single light-emitting element ED, or may include multiple light-emitting elements ED. For example, the light-emitting unit EMU may include a single light-emitting element ED as shown in FIG. 4. In another embodiment, the light-emitting unit EMU may include multiple light-emitting elements ED connected in parallel, in series, or in series-parallel between the pixel circuit PXC and the second power line VSL.

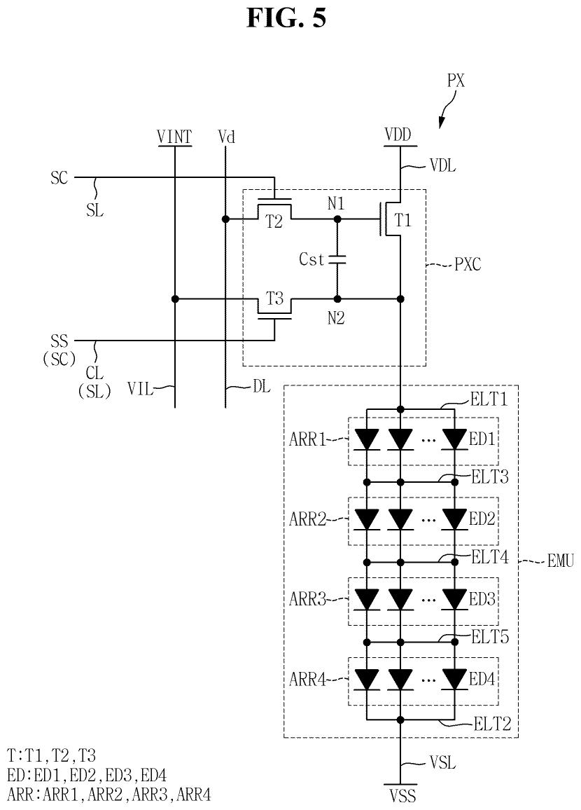

FIG. 5 is a circuit schematic of an equivalent circuit of the pixel PX according to one embodiment. For example, FIG. 5 shows a pixel PX according to an embodiment different from the embodiment of FIG. 4 with respect to the light-emitting unit EMU.

Referring to FIGS. 4 and 5, the light-emitting unit EMU may include light-emitting elements ED connected (for example, connected in a forward direction) between a first pixel electrode ELT1 (also referred to as “first electrode” or “first contact electrode”) and a second pixel electrode ELT2 (also referred to as “second electrode” or “second contact electrode”). For example, the light-emitting unit EMU may include light-emitting elements ED connected or arranged in four series stages sequentially connected between the first pixel electrode ELT1 and the second pixel electrode ELT2. In one embodiment, the first pixel electrode ELT1 may be an anode electrode of the light-emitting unit EMU, and the second pixel electrode ELT2 may be a cathode electrode of the light-emitting unit EMU.

In describing embodiments, the series stage included in the light-emitting unit EMU and through which the driving current corresponding to the data signal may flow will be referred to as “array,” “series array,” or “light-emitting element array.” For example, a K (K being a natural number)^{th} series stage of the light-emitting unit EMU may be referred to as “K^{th} series stage” or “K^{th} light-emitting element array.” For example, in case that the light-emitting unit EMU includes light-emitting elements ED arranged in four series stages as in the embodiment of FIG. 5, the light-emitting unit EMU may include a first array ARR1, a second array ARR2, a third array ARR3, and a fourth array ARR4 that are sequentially connected between the first pixel electrode ELT1 and the second pixel electrode ELT2.

In one embodiment, each array ARR may include at least two light-emitting elements ED. For example, the first array ARR1 may include at least two first light-emitting elements ED1 connected or arranged in parallel between the first pixel electrode ELT1 and the third pixel electrode ELT3, and the second array ARR2 may include at least two second light-emitting elements ED2 connected or arranged in parallel between the third pixel electrode ELT3 and the fourth pixel electrode ELT4. The third array ARR3 may include at least two third light-emitting elements ED3 connected or arranged in parallel between the fourth pixel electrode ELT4 and the fifth pixel electrode ELT5, and the fourth array ARR4 may include at least two fourth light-emitting elements ED4 connected or arranged in parallel between the fifth pixel electrode ELT5 and the second pixel electrode ELT2.

In an embodiment in which the light-emitting unit EMU includes multiple light-emitting elements ED, the arrangement structure of the light-emitting elements ED may be variously changed depending on embodiments. For example, the light-emitting unit EMU may include light-emitting elements ED connected in parallel to each other (for example, connected in parallel in the forward direction between the first pixel electrode ELT1 and the second pixel electrode ELT2) in a single array ARR, may include light-emitting elements ED connected or arranged in two or three arrays ARR, or may include light-emitting elements ED connected or arranged in five or more arrays ARR. Each array ARR may include at least one light-emitting element ED connected or arranged in the forward direction between the first pixel electrode ELT1 and the second pixel electrode ELT2. In one embodiment, each array ARR may include at least two light-emitting elements ED connected in parallel to each other.

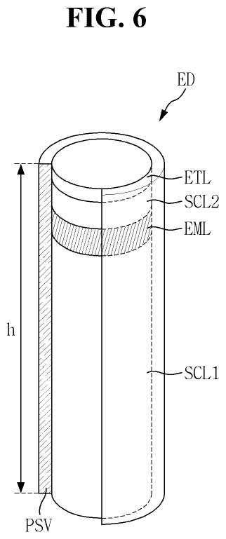

FIG. 6 is a perspective view showing the light-emitting element ED according to one embodiment.

Referring to FIG. 6, the light-emitting element ED may be a light-emitting diode. In one embodiment, the light-emitting element ED may be an inorganic light-emitting diode made of an inorganic material, and may have a micrometer or nanometer size. For example, the light-emitting element ED may be made of gallium nitride (GaN) or another inorganic material, and the width (or diameter) and length h of the light-emitting element ED may each be less than or equal to about 100 μm.

The light-emitting element ED may be grown on a semiconductor substrate such as a silicon substrate or a sapphire substrate and etched to have a desired size and shape. In one embodiment, multiple light-emitting elements ED may be formed simultaneously on a semiconductor substrate. The light-emitting elements ED may be supplied to emission areas EA of the pixels PX by an inkjet printing method, and may be aligned and fixed in at least one array ARR located in each emission area EA.

The light-emitting element ED may include a first semiconductor layer SCL1, a light-emitting layer EML (for example, the active layer of the light-emitting element ED), and a second semiconductor layer SCL2. The first semiconductor layer SCL1, the light-emitting layer EML, and the second semiconductor layer SCL2 may be sequentially disposed or stacked in a direction (for example, the longitudinal direction of the light-emitting element ED).

In one embodiment, the light-emitting element ED may further include an electrode layer ETL disposed at an end. For example, the light-emitting element ED may further include an electrode layer ETL disposed on the second semiconductor layer SCL2.

In one embodiment, the light-emitting element ED may further include a passivation film PSV surrounding at least the light-emitting layer EML and surrounding at least a part of the first semiconductor layer SCL1 and the second semiconductor layer SCL2. In FIG. 6, a part of the passivation film PSV is omitted to show the structure of the light-emitting element ED, but the passivation film PSV may entirely surround the side surfaces of the first semiconductor layer SCL1, the light-emitting layer EML, and the second semiconductor layer SCL2. The passivation film PSV may partially or entirely surround the side surface of the electrode layer ETL, or may not surround the side surface of the electrode layer ETL. The passivation film PSV may expose ends of the light-emitting element ED.

The first semiconductor layer SCL1 may include a first conductivity type semiconductor layer including a first conductivity type dopant. For example, the first semiconductor layer SCL1 may be an N-type semiconductor layer including an N-type dopant.

In one embodiment, the first semiconductor layer SCL1 may include a nitride-based semiconductor material or a phosphide-based semiconductor material. For example, the first semiconductor layer SCL1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The first semiconductor layer SCL1 may include other materials. In one embodiment, the first semiconductor layer SCL1 may include an N-type dopant such as Si, Ge, or Sn. The first semiconductor layer SCL1 may include other dopants.

The light-emitting layer EML may be disposed on the first semiconductor layer SCL1. The light-emitting layer EML may include a single or multiple quantum well structure. In case that a voltage higher than a threshold voltage is applied to ends of the light-emitting element ED, electron-hole pairs may recombine in the light-emitting layer EML. Accordingly, light may be emitted from the light-emitting element ED.

In one embodiment, the light-emitting layer EML may emit light in a visible light wavelength band, for example, light in a wavelength band in a range of approximately 400 nm to approximately 900 nm. For example, the light-emitting layer EML may emit blue light having a peak wavelength in a range of approximately 440 nm to approximately 480 nm, green light having a peak wavelength in a range of approximately 510 nm to approximately 550 nm, or red light having a peak wavelength in a range of approximately 610 nm to approximately 650 nm. The light-emitting layer EML may emit light in other colors and/or wavelength bands other than the colors and/or wavelength bands exemplified above.

In one embodiment, the light-emitting layer EML may include a nitride-based semiconductor material or a phosphide-based semiconductor material. For example, the light-emitting layer EML may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. The light-emitting layer EML may include other materials.

The second semiconductor layer SCL2 may be disposed on the light-emitting layer EML. The second semiconductor layer SCL2 may include a second conductivity type semiconductor layer including a second conductivity type dopant. For example, the second semiconductor layer SCL2 may be a P-type semiconductor layer including a P-type dopant.

In one embodiment, the second semiconductor layer SCL2 may include a nitride-based semiconductor material or a phosphide-based semiconductor material. For example, the second semiconductor layer SCL2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AIP, and InP. The second semiconductor layer SCL2 may include other materials. In one embodiment, the second semiconductor layer SCL2 may include a P-type dopant such as Mg. The second semiconductor layer SCL2 may include other dopants.

In one embodiment, the first semiconductor layer SCL1 and the second semiconductor layer SCL2 may have different lengths (or thicknesses) in the longitudinal direction of the light-emitting element ED. For example, the first semiconductor layer SCL1 may have a length (or thickness) greater than a length (or thickness) of the second semiconductor layer SCL2 in the longitudinal direction of the light-emitting element ED.

The electrode layer ETL may be disposed on the second semiconductor layer SCL2. The electrode layer ETL may be a contact electrode that protects the second semiconductor layer SCL2 and readily connects the second semiconductor layer SCL2 to at least one circuit element, electrode, and/or wire.

In one embodiment, the electrode layer ETL may include a metal or a metal oxide. For example, the electrode layer ETL may include at least one of chromium (Cr), titanium (Ti), aluminum (Al), gold (Au), nickel (Ni), or copper (Cu), an oxide thereof, and an alloy thereof, or a transparent conductive material such as indium tin oxide (ITO), indium zinc oxide (IZO), indium tin zinc oxide (ITZO), zinc oxide (ZnO), or indium oxide (In₂O₃). The electrode layer ETL may include other conductive materials. In one embodiment, the electrode layer ETL may be substantially transparent. Accordingly, light generated from the light-emitting element ED may pass through the electrode layer ETL.

The passivation film PSV may surround at least a side surface of the light-emitting layer EML. In one embodiment, the passivation film PSV may surround the side surfaces (for example, the etched surfaces) of the first semiconductor layer SCL1, the light-emitting layer EML, the second semiconductor layer SCL2, and/or the electrode layer ETL. The passivation film PSV may include silicon oxide (SiOₓ), silicon nitride (SiNₓ), silicon oxynitride (SiOₓN_{y}), aluminum oxide (Al₂O₃), and aluminum nitride (AlN), or another insulating material. The passivation film PSV may be formed as a single or multiple insulating layers. The passivation film PSV may prevent the light-emitting layer EML from being in direct contact with pixel electrodes (for example, the first pixel electrode ELT1 and the second pixel electrode ELT2), and may protect the outer surface of the light-emitting element ED.

In one embodiment, the length h of the light-emitting element ED may be in a range of approximately 1 μm to approximately 10 μm. For example, the length h of the light-emitting element ED may be in a range of approximately 2 μm to approximately 6 μm. In one embodiment, the width (or the diameter) of the light-emitting element ED may be in a range of approximately 30 nm to approximately 700 nm. The light-emitting element ED may have a rod shape extending in a direction. For example, the aspect ratio of the light-emitting element ED may be in a range of approximately 1.2 to approximately 100. However, the shape or size of the light-emitting element ED may be variously changed depending on embodiments.

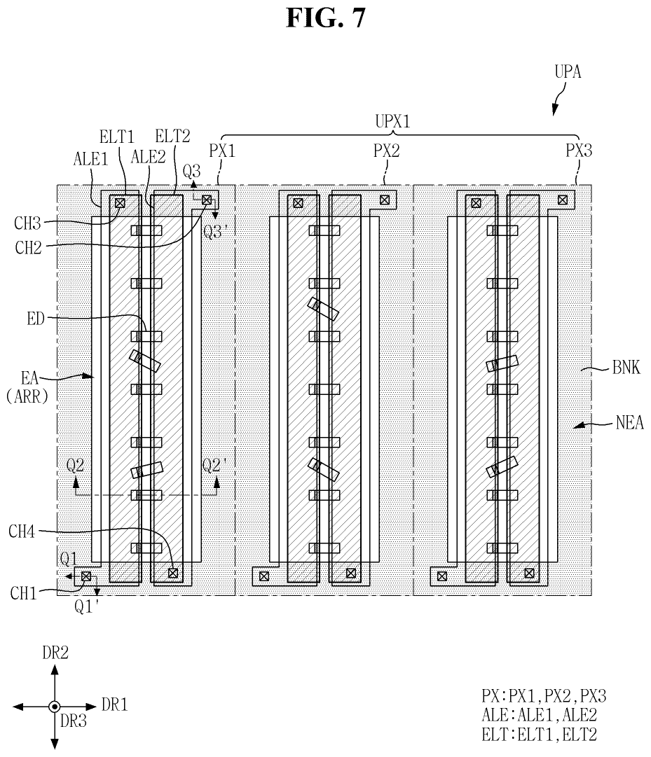

FIG. 7 is a plan view showing the unit pixel area UPA according to one embodiment. For example, FIG. 7 shows the unit pixel area UPA where one unit pixel UPX including the first pixel PX1, the second pixel PX2, and the third pixel PX3 is disposed. FIG. 7 shows a schematic structure of the unit pixel UPX with respect to the light-emitting unit EMU of each pixel PX.

Referring to FIGS. 1 to 7, the display device DD may include unit pixels UPX disposed in the unit pixel areas UPA of the display area DPA. Each unit pixel UPX may include multiple pixels PX that emit light of different colors. In one embodiment, each unit pixel UPX may include the first pixel PX1, the second pixel PX2, and the third pixel PX3. Each unit pixel UPX may further include the fourth pixel PX4, or may not include the fourth pixel PX4.

Each pixel PX may include the emission area EA where the light-emitting unit EMU of the corresponding pixel PX is disposed. The emission area EA may include one or more arrays ARR each including at least one light-emitting element ED. In one embodiment, two or more light-emitting elements ED electrically connected between the first pixel electrode ELT1 and the second pixel electrode ELT2 may be arranged in each array ARR. One pixel electrode ELT (for example, the first pixel electrode ELT1) may be disposed on an end of each of the light-emitting elements ED, and another pixel electrode ELT (for example, the second pixel electrode ELT2) may be disposed on another end of each of the light-emitting elements ED.

Each pixel PX may further include at least one pair of alignment electrodes ALE disposed adjacent to the light-emitting elements ED. For example, each pixel PX may further include a first alignment electrode ALE1 and a second alignment electrode ALE2 that are disposed in at least the emission area EA and face each other.

In one embodiment, the alignment electrodes ALE may be disposed under the light-emitting elements ED, and the light-emitting elements ED may be arranged between the alignment electrodes ALE. For example, in a plan view, at least a part of each of the light-emitting elements ED may be disposed between a pair of alignment electrodes ALE.

The alignment electrodes ALE may be generally disposed in each array ARR of the emission area EA, and may be spaced apart from each other. In one embodiment, the alignment electrodes ALE may be spaced apart from each other in the first direction DR1, and may each extend in the second direction DR2, but the disclosure is not limited thereto. The shape, size, number, and/or arrangement structure of the alignment electrodes ALE may be variously changed depending on embodiments.

In one embodiment, the first alignment electrode ALE1 may be connected to the first power line VDL through a first contact hole CH1 and/or at least one circuit element (for example, the first transistor T1 of FIG. 4 or 5), and the second alignment electrode ALE2 may be connected to the second power line VSL through a second contact hole CH2. In one embodiment, the first alignment electrode ALE1 and the second alignment electrode ALE2 may extend to the non-emission area NEA adjacent to the emission area EA, and the first contact hole CH1 and the second contact hole CH2 may be formed in the non-emission area NEA, but the disclosure is not limited thereto.

During the manufacturing process of the display device DD, an alignment signal may be applied to the first alignment electrode ALE1 and the second alignment electrode ALE2. For example, in the step of aligning the light-emitting elements ED supplied to each emission area EA, an alignment signal may be applied to the first alignment electrode ALE1 and the second alignment electrode ALE2. Accordingly, an electric field may be formed around the first alignment electrode ALE1 and the second alignment electrode ALE2 to align the light-emitting elements ED directionally.

The light-emitting elements ED may be arranged in the emission area EA of each pixel PX. In one embodiment, the light-emitting elements ED may be arranged and/or aligned between the alignment electrodes ALE. For example, at least a part of each of the light-emitting element ED may be disposed between a pair of alignment electrodes ALE. In one embodiment, the light-emitting elements ED may be substantially arranged in the second direction DR2, and each of the light-emitting elements ED may be substantially aligned in the first direction DR1. However, the disclosure is not limited thereto. For example, at least one light-emitting element ED may be arranged or aligned in a diagonal direction intersecting the first direction DR1 and the second direction DR2. Further, although FIG. 3 illustrates only the light-emitting elements ED that are appropriately or completely connected to the first pixel electrode ELT1 and the second pixel electrode ELT2, the disclosure is not limited thereto. For example, at least one light-emitting element (for example, a dummy light-emitting element or a non-effective light-emitting element) may not be appropriately aligned or connected to the first pixel electrode ELT1 and the second pixel electrode ELT2 and thus may not emit light in the emission area EA.

The ends of each of the light-emitting elements ED may or may not overlap at least one alignment electrode ALE in the third direction DR3. For example, ends (for example, P-type ends connected to the first pixel electrode ELT1) of the light-emitting elements ED may be adjacent to the first alignment electrode ALE1, and may or may not overlap the first alignment electrode ALE1 in the third direction DR3. The another ends (for example, N-type ends connected to the second pixel electrode ELT2) of the light-emitting elements ED may be adjacent to the second alignment electrode ALE2, and may or may not overlap the second alignment electrode ALE2 in the third direction DR3.

Although FIG. 7 illustrates that the same number of light-emitting elements ED are disposed in each pixel PX, the disclosure is not limited thereto. For example, the pixels PX may include different numbers of light-emitting elements ED. Further, although FIG. 7 illustrates an embodiment the light-emitting elements ED are arranged at relatively uniform intervals, the disclosure is not limited thereto, and the light-emitting elements ED may be arranged at non-uniform intervals. Although FIG. 7 illustrates that the light-emitting elements ED do not overlap each other in the third direction DR3, the disclosure is not limited thereto, and some of the light-emitting elements ED may overlap each other in a clumped manner.

The first pixel electrode ELT1 may be disposed on first ends of the light-emitting elements ED and connected to the first ends of the light-emitting elements ED. In one embodiment, the first pixel electrode ELT1 may be connected to the first alignment electrode ALE1 through a third contact hole CH3 penetrating the insulating layer between the first pixel electrode ELT1 and the first alignment electrode ALE1, or may be connected to the first alignment electrode ALE1 through an opening in which the insulating layer is opened wider in the emission area EA. In one embodiment, the first pixel electrode ELT1 may be connected to at least one circuit element and/or the first power line VDL through the first alignment electrode ALE1. In another embodiment, the first pixel electrode ELT1 may be connected to (e.g., directly connected to) at least one circuit element and/or the first power line VDL without passing through the first alignment electrode ALE1.

The second pixel electrode ELT2 may be disposed on second ends of the light-emitting elements ED and connected to the second ends of the light-emitting elements ED. In one embodiment, the second pixel electrode ELT2 may be connected to the second alignment electrode ALE2 through a fourth contact hole CH4 penetrating the insulating layer between the second pixel electrode ELT2 and the second alignment electrode ALE2, or may be connected to the second alignment electrode ALE2 through an opening in which the insulating layer is opened wider in the emission area EA. In one embodiment, the second pixel electrode ELT2 may be connected to the second power line VSL through the second alignment electrode ALE2. In another embodiment, the second pixel electrode ELT2 may be connected to (e.g., directly connected to) the second power line VSL without passing through the second alignment electrode ALE2.

In one embodiment, the display device DD may further include a bank BNK disposed in the display area DPA. The bank BNK may have openings corresponding to the emission areas EA of the pixels PX, and may be disposed in the non-emission area NEA. For example, the bank BNK may be disposed in the non-emission area NEA to surround the emission areas EA of the pixels PX.

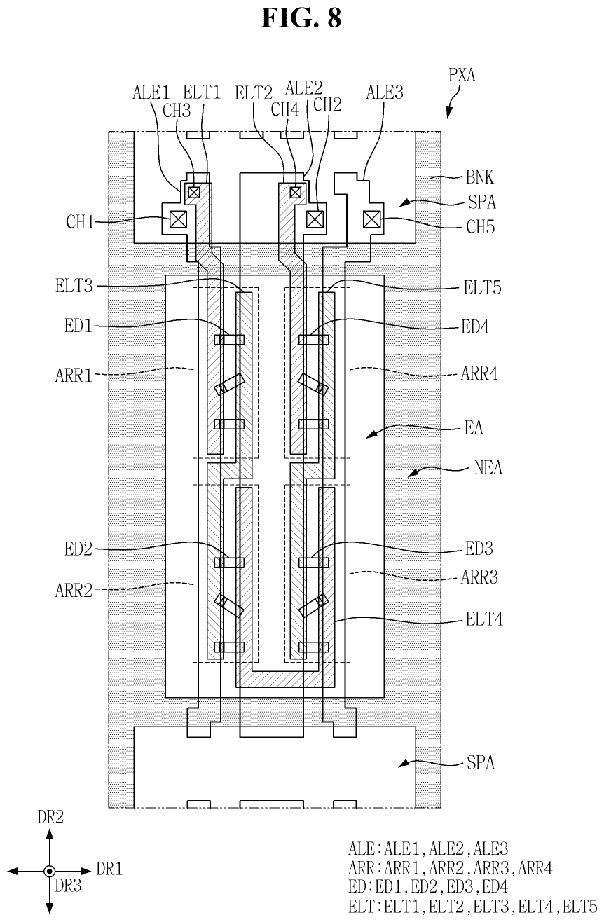

FIG. 8 is a plan view showing the pixel area PXA according to one embodiment. For example, FIG. 8 shows the pixel area PXA disposed in each unit pixel area UPA and where one pixel PX among the pixels PX forming the unit pixel UPX of the unit pixel area UPA is disposed. FIG. 8 shows a schematic structure of each pixel PX with respect to the light-emitting unit EMU of the pixel PX including four arrays ARR.

Referring to FIGS. 1 to 8, at least one pixel PX among the pixels PX included in the unit pixel UPX may include light-emitting elements ED disposed in the arrays ARR. For example, the emission area EA may include the first array ARR1, the second array ARR2, the third array ARR3, and the fourth array ARR4, and the pixel PX may include the first light-emitting elements ED1, the second light-emitting elements ED2, the third light-emitting elements ED3, and the fourth light-emitting elements ED4 respectively arranged in the first array ARR1, the second array ARR2, the third array ARR3, and the fourth array ARR4.

In one embodiment, the bank BNK may include an opening of a size corresponding to the emission area EA including the arrays ARR, but the disclosure is not limited thereto. For example, the bank BNK according to another embodiment may include openings corresponding to the respective arrays ARR. For example, the bank BNK may include multiple openings disposed in the emission area EA of each pixel PX, and each of the openings may have a size corresponding to at least one array ARR (for example, one array ARR or two arrays ARR) among the arrays ARR disposed in the corresponding emission area EA and surround the at least one array ARR.

In one embodiment, the bank BNK may further include openings corresponding to a separation area SPA located adjacent to at least one side of the emission area EA. For example, the bank BNK may be opened in the separation areas SPA located on sides of the emission area EA in the second direction DR2. At least one alignment electrode ALE may be cut off in each separation area SPA, so that an end of the at least one alignment electrode ALE may be disposed in each separation area SPA.

In one embodiment, a pixel PX may include three or more alignment electrodes ALE. For example, the first alignment electrode ALE1, the second alignment electrode ALE2, and the third alignment electrode ALE3 that are spaced apart from each other may be disposed in an emission area EA of the pixel PX. In one embodiment, the first alignment electrode ALE1, the second alignment electrode ALE2, and the third alignment electrode ALE3 may be sequentially disposed in the first direction DR1, but the disclosure is not limited thereto. In one embodiment, ends of the first alignment electrode ALE1, the second alignment electrode ALE2, and the third alignment electrode ALE3 may be disposed in the separation areas SPA. However, the disclosure is not limited thereto. For example, the second alignment electrode ALE2 connected to the second power line VSL may be cut off or may not be cut off in the separation areas SPA. In one embodiment, the first alignment electrode ALE1, the second alignment electrode ALE2, and the third alignment electrode ALE3 may be connected to at least one circuit element and/or wire through the first contact hole CH1, the second contact hole CH2, and the fifth contact hole CH5, respectively. In one embodiment, the third alignment electrode ALE3 may be connected to the first power line VDL or another wire through the fifth contact hole CH5, so that an alignment signal may be applied to the third alignment electrode ALE3 during the manufacturing process of the display device DD.

The first light-emitting elements ED1 and the second light-emitting elements ED2 may be disposed between the first alignment electrode ALE1 and the second alignment electrode ALE2. In one embodiment, the first light-emitting elements ED1 and the second light-emitting elements ED2 may be sequentially disposed in the second direction DR2.

The first pixel electrode ELT1 may be disposed on first ends of the first light-emitting elements ED1. The first ends of the first light-emitting elements ED1 may be electrically connected to the first pixel electrode ELT1. The third pixel electrode ELT3 (or a part of the third pixel electrode ELT3) may be disposed on second ends of the first light-emitting elements ED1. The second ends of the first light-emitting elements ED1 may be electrically connected to the third pixel electrode ELT3. The area where the first light-emitting elements ED1 are disposed may correspond to the first array ARR1 (also referred to as “first light-emitting element arrangement area” or “first sub-emission area”).

The third pixel electrode ELT3 (or another part of the third pixel electrode ELT3) may be disposed on first ends of the second light-emitting elements ED2. The first ends of the second light-emitting elements ED2 may be electrically connected to the third pixel electrode ELT3. The fourth pixel electrode ELT4 (or a part of the fourth pixel electrode ELT4) may be disposed on second ends of the second light-emitting elements ED2. The second ends of the second light-emitting elements ED2 may be electrically connected to the fourth pixel electrode ELT4. The area where the second light-emitting elements ED2 are disposed may correspond to the second array ARR2 (also referred to as “second light-emitting element arrangement area” or “second sub-emission area”).

The fourth pixel electrode ELT4 (or another part of the fourth pixel electrode ELT4) may be disposed on first ends of the third light-emitting elements ED3. The first ends of the third light-emitting elements ED3 may be electrically connected to the fourth pixel electrode ELT4. The fifth pixel electrode ELT5 (a part of the fifth pixel electrode ELT5) may be disposed on second ends of the third light-emitting elements ED3. The second ends of the third light-emitting elements ED3 may be electrically connected to the fifth pixel electrode ELT5. The area where the third light-emitting elements ED3 are disposed may correspond to the third array ARR3 (also referred to as “third light-emitting element arrangement area” or “third sub-emission area”).

The fifth pixel electrode ELT5 (or another part of the fifth pixel electrode ELT5) may be disposed on first ends of the fourth light-emitting elements ED4. The first ends of the fourth light-emitting elements ED4 may be electrically connected to the fifth pixel electrode ELT5. The second pixel electrode ELT2 may be disposed on second ends of the fourth light-emitting elements ED4. The second ends of the fourth light-emitting elements ED4 may be electrically connected to the second pixel electrode ELT2. The area where the fourth light-emitting elements ED4 are disposed may correspond to the fourth array ARR4 (also referred to as “fourth light-emitting element arrangement area” or “fourth sub-emission area”).

In addition to the embodiments of FIGS. 7 and 8, the structure of each pixel PX (for example, the light-emitting unit EMU) may be variously changed. In an embodiment, each pixel PX may further include additional components. For example, each pixel PX may further include a protruding structure (for example, a reflective partition wall) disposed around the light-emitting elements ED.

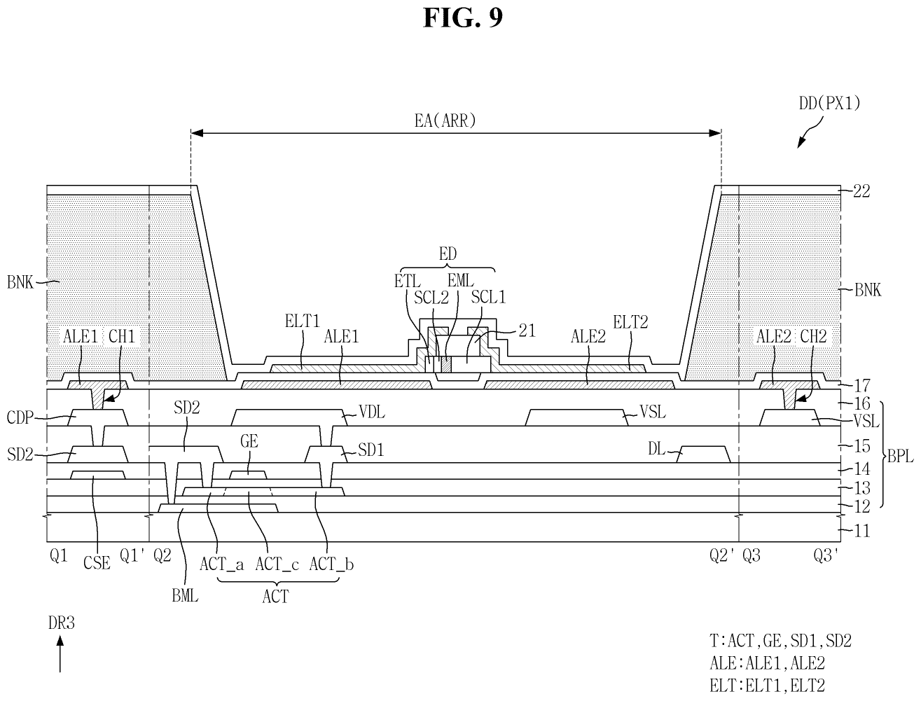

FIG. 9 is a schematic cross-sectional view illustrating the display device DD according to one embodiment. For example, FIG. 9 shows a cross section of the first pixel PX1 taken along lines Q1-Q1′, Q2-Q2′, and Q3-Q3′ of FIG. 7. Although FIG. 9 shows only the cross section of the first pixel PX1, other pixels PX (for example, the second pixel PX2 and the third pixel PX3) may have a cross-sectional structure that is substantially the same or similar to the cross-sectional structure of first pixel PX1 of FIG. 9. The cross section of each pixel PX may be variously changed without being limited to the embodiment illustrated in FIG. 9. Further, depending on embodiments, some pixels PX may have a cross-sectional structure different from the cross-sectional structures of other pixels PX.

Referring to FIGS. 1 to 9, the display device DD may include a base substrate 11, the light-emitting elements ED disposed on the base substrate 11, the pixel electrodes ELT (also referred to as “contact electrodes”) connected to the light-emitting elements ED, and the alignment electrodes ALE disposed adjacent to the light-emitting elements ED. The display device DD may further include insulating layers.

In one embodiment, the display device DD may further include a panel circuit layer BPL (or a backplane circuit layer) disposed between the base substrate 11 and the alignment electrodes ALE. The panel circuit layer BPL, which is a layer in which circuit elements, wires, and/or pads provided in the display panel are disposed, may include at least one semiconductor layer, multiple conductive layers, and multiple insulating layers. The location of the panel circuit layer BPL may vary depending on embodiments. In another embodiment, the display device DD may not include the panel circuit layer BPL. For example, the alignment electrodes ALE may be disposed on (e.g., disposed directly on) the base substrate 11, or on a barrier layer or a buffer layer disposed on the base substrate 11.

The base substrate 11, which is a base member for forming the display panel of the display device DD, may form a base surface of the display panel. The base substrate 11 may be formed of an insulating material such as glass, quartz, or a polymer resin. The base substrate 11 may be a rigid substrate or a flexible substrate which can be bent, folded or rolled.

A light blocking layer BML may be disposed on the base substrate 11. The light blocking layer BML may overlap an active layer ACT of at least one transistor T provided in each pixel PX of the display device DD in the third direction DR3. In FIG. 3, only one transistor T provided in the first pixel PX1 (for example, the first transistor T1 of FIG. 4 or 5) is illustrated as a representative of circuit elements that may be disposed in the panel circuit layer BPL.

The light blocking layer BML may include a material that blocks light, thereby preventing light from being incident on the active layer ACT of the transistor T. For example, the light blocking layer BML may be formed of an opaque metal material that blocks transmission of light. In another embodiment, the display device DD may not include the light blocking layer BML.

A buffer layer 12 may be disposed on the light blocking layer BML. For example, the buffer layer 12 may be disposed on the base substrate 11 and may cover the light blocking layer BML. The buffer layer 12 may include at least one inorganic insulating layer, and may protect the pixels PX from moisture permeating through the base substrate 11 or the like. For example, the buffer layer 12 may include silicon oxide (SiOₓ), silicon nitride (SiNₓ), silicon oxynitride (SiOₓN_{y}), or another inorganic insulating material.

A semiconductor layer may be disposed on the buffer layer 12. The semiconductor layer may include the active layer ACT of the transistor T. The active layer ACT may include polycrystalline silicon, monocrystalline silicon, an oxide semiconductor, or another semiconductor material. The active layer ACT may include a channel region ACT_c overlapping a gate electrode GE of the corresponding transistor T in the third direction DR3, and conductive regions ACT_a and ACT_b (e.g. source and drain regions) located on sides of the channel region ACT_c.

A first insulating layer 13 may be disposed on the semiconductor layer. For example, the first insulating layer 13 may be disposed on the buffer layer 12, and may cover the patterns (for example, the active layer ACT) of the semiconductor layer. In one embodiment, the first insulating layer 13 may include an inorganic insulating material (for example, silicon oxide (SiOₓ), silicon nitride (SiNₓ), silicon oxynitride (SiOₓN_{y}), or another inorganic insulating material).

A first conductive layer may be disposed on the first insulating layer 13. The first conductive layer may include a first capacitor electrode CSE and the gate electrode GE of the transistor T. The gate electrode GE may overlap the channel region ACT_c of the active layer ACT in the third direction DR3. The first capacitor electrode CSE may overlap a second source/drain electrode SD2 of the transistor T in the thickness direction (or the third direction DR3). In some embodiments, the first capacitor electrode CSE may be connected to the gate electrode GE. For example, the first capacitor electrode CSE and the gate electrode GE may be formed as one integrated pattern. Since the first capacitor electrode CSE overlaps the second source/drain electrode SD2, a capacitor (for example, the capacitor Cst of each pixel PX) may be formed between the first capacitor electrode CSE and the second source/drain electrode SD2.

The first conductive layer may be made of at least one conductive material (for example, at least one of molybdenum (Mo), aluminum (Al), chromium (Cr), gold (Au), titanium (Ti), nickel (Ni), neodymium (Nd), copper, an alloy thereof, and another conductive material). The first conductive layer may be formed as a single layer or multiple layers.

A second insulating layer 14 may be disposed on the first conductive layer. For example, the second insulating layer 14 may be disposed on the first insulating layer 13, and may cover the patterns (for example, the first capacitor electrode CSE and the gate electrode GE of the transistor T) of the first conductive layer. In one embodiment, the second insulating layer 14 may include an inorganic insulating material (e.g., silicon oxide (SiOₓ), silicon nitride (SiNₓ), silicon oxynitride (SiOₓN_{y}), or another inorganic insulating material).

A second conductive layer may be disposed on the second insulating layer 14. The second conductive layer may include the first source/drain electrode SD1 and a second source/drain electrode SD2 of the first transistor T, and the data line DL. The first source/drain electrode SD1 may be one of the source electrode and the drain electrode of the transistor T, and the second source/drain electrode SD2 may be another one of the source electrode and the drain electrode of the transistor T.

The first source/drain electrode SD1 and the second source/drain electrode SD2 of the transistor T may be connected to the conductive regions ACT_a and ACT_b of the active layer ACT. For example, the first source/drain electrode SD1 of the transistor T may be connected to the conductive region ACT_a (for example, the source region) located on a side of the active layer ACT through a contact hole penetrating the second insulating layer 14 and the first insulating layer 13, and the second source/drain electrode SD2 of the transistor T may be connected to the conductive region ACT_b (for example, the drain region) located on another side of the active layer ACT through another contact hole penetrating the second insulating layer 14 and the first insulating layer 13. In one embodiment, the second source/drain electrode SD2 of the transistor T may be electrically connected to the light blocking layer BML through a contact hole penetrating the second insulating layer 14, the first insulating layer 13, and the buffer layer 12.

The data line DL may apply a data signal to another transistor (not illustrated in FIG. 9) provided in the pixel PX. For example, the data line DL may be connected to the second transistor T2 of FIG. 4 or FIG. 5.

The second conductive layer may include at least one conductive material (for example, at least one of molybdenum (Mo), aluminum (Al), chromium (Cr), gold (Au), titanium (Ti), nickel (Ni), neodymium (Nd), copper (Cu), an alloy thereof, and another conductive material). The second conductive layer may be formed as a single layer or multiple layers.

A third insulating layer 15 may be disposed on the second conductive layer. For example, the third insulating layer 15 may be disposed on the second insulating layer 14, and may cover the patterns of the second conductive layer. In one embodiment, the third insulating layer 15 may include an inorganic insulating material (e.g., silicon oxide (SiOₓ), silicon nitride (SiNₓ), silicon oxynitride (SiOₓN_{y}), or another inorganic insulating material).

A third conductive layer may be disposed on the third insulating layer 15. The third conductive layer may include the first power line VDL, the second power line VSL, and a first conductive pattern CDP. The first conductive pattern CDP may be electrically connected to the second source/drain electrode SD2 of the transistor T through a contact hole formed in the third insulating layer 15. The first conductive pattern CDP may be connected to the first alignment electrode ALE1 through the first contact hole CH1.

The third conductive layer may include at least one conductive material (e.g., molybdenum (Mo), aluminum (Al), chromium (Cr), gold (Au), titanium (Ti), nickel (Ni), neodymium (Nd), and copper. (Cu), an alloy thereof, or another conductive material). The third conductive layer may be formed as a single layer or multiple layers.

A fourth insulating layer 16 (for example, a planarization layer) may be disposed on the third conductive layer. The fourth insulating layer 16 may include an organic insulating material (e.g., polyimide (PI) or another organic insulating material). The surface of the fourth insulating layer 16 may be substantially flat.

The first conductive layer to the fourth insulating layer 16 (or the light blocking layer BML to the fourth insulating layer 16) described above may constitute the panel circuit layer BPL in which wires and circuit elements (for example, the capacitors Cst and the transistors T constituting the pixel circuits PXC of the pixels PX) provided in the display panel are provided. In one embodiment, the base substrate 11 and the panel circuit layer BPL may constitute a lower substrate (for example, a backplane substrate of the display panel) of the display device DD.

The light-emitting element layer including the light-emitting units EMU of the pixels PX may be disposed on the panel circuit layer BPL. For example, the light-emitting element layer may be disposed on the fourth insulating layer 16. In one embodiment, the light-emitting element layer may include the alignment electrodes ALE, the light-emitting elements ED, and the pixel electrodes ELT. The light-emitting element layer may further include a fifth insulating layer 17, the bank BNK, a sixth insulating layer 21, and a seventh insulating layer 22 that are disposed between or around the alignment electrodes ALE, the light-emitting elements ED, and the pixel electrodes ELT.

For example, the alignment electrodes ALE may be disposed on the panel circuit layer BPL. For example, the alignment electrodes ALE may be disposed on the fourth insulating layer 16. Each of the alignment electrodes ALE may be a single-layer or multi-layer electrode including at least one conductive material. In one embodiment, each of the alignment electrodes ALE may be a reflective electrode including a highly reflective conductive material (for example, silver (Ag), copper (Cu), aluminum (Al), or another reflective metal). Accordingly, the light emission efficiency of each pixel PX may be increased.

In one embodiment, the first alignment electrode ALE1 may be electrically connected to at least one transistor T provided in each pixel PX through the first contact hole CH1. For example, the first alignment electrode ALE1 may be in contact with the first conductive pattern CDP through the first contact hole CH1 penetrating the fourth insulating layer 16, and may be electrically connected to at least one transistor T provided in the corresponding pixel PX through the first conductive pattern CDP.

In one embodiment, the second alignment electrode ALE2 may be electrically connected to the second power line VSL through the second contact hole CH2. For example, the second alignment electrode ALE2 may be in contact with the second power line VSL through the second contact hole CH2 penetrating the fourth insulating layer 16.

The fifth insulating layer 17 may be disposed on the alignment electrodes ALE. For example, the fifth insulating layer 17 may be disposed on the fourth insulating layer 16, and may cover the alignment electrodes ALE.

The light-emitting elements ED may be disposed on the fifth insulating layer 17. Each light-emitting element ED may include the first semiconductor layer SCL1, the second semiconductor layer SCL2, and the light-emitting layer EML interposed between the first and second semiconductor layers SCL1 and SCL2. In one embodiment, the light-emitting element ED may further include at least one of the electrode layer ETL or a passivation film (for example, the passivation film PSV of FIG. 6).

In one embodiment, the light-emitting element ED may be a light-emitting diode having a micrometer or nanometer size and made of an inorganic material. For example, the light-emitting element ED may be a micro LED or a nano LED having a rod shape extending in a direction as shown in FIG. 6.

In one embodiment, the sixth insulating layer 21 (or an insulating pattern) may be disposed on a part of the light-emitting elements ED. For example, the sixth insulating layer 21 may be disposed on a part of each of the light-emitting elements ED including the light-emitting layer EML, and may not be disposed on another part including ends of each of the light-emitting elements ED. Accordingly, ends of each of the light-emitting elements ED may be exposed without being covered by the sixth insulating layer 21. The sixth insulating layer 21 may protect the light-emitting elements ED and, at the same time, may fix the light-emitting elements ED to aligned positions during the manufacturing process of the display device DD. In another embodiment, the display device DD may not include the sixth insulating layer 21.

The pixel electrodes ELT may be disposed on ends of each of the light-emitting elements ED. For example, the first pixel electrode ELT1 may be disposed on the first end (for example, P-type end) of each of the light-emitting elements ED, and the second pixel electrode ELT2 may be disposed on the second end (for example, N-type end) of each of the light-emitting elements ED. While the display device DD is being driven, an electrical signal may be applied to the light-emitting elements ED through the first pixel electrode ELT1 and the second pixel electrode ELT2.

Each of the pixel electrodes ELT may be a single-layer or multi-layer electrode including at least one conductive material. In one embodiment, the pixel electrodes ELT may be transparent electrodes including a transparent conductive material (for example, indium tin oxide (ITO), indium zinc oxide (IZO), indium tin-zinc oxide (ITZO), or another transparent conductive material), so that light emitted from the light-emitting elements ED may pass through the pixel electrodes ELT.

The seventh insulating layer 22 may be disposed on the pixel electrodes ELT. For example, the seventh insulating layer 22 may be disposed on the fifth insulating layer 17 and the sixth insulating layer 21, and may cover the pixel electrodes ELT. In one embodiment, the seventh insulating layer 22 may be a common layer disposed entirely in the display area DPA, and may further cover the bank BNK.

Each of the fifth insulating layer 17, the sixth insulating layer 21, and the seventh insulating layer 22 may be a single-layer or multi-layer insulating layer including an inorganic insulating material and/or an organic insulating material. For example, each of the fifth insulating layer 17, the sixth insulating layer 21, and the seventh insulating layer 22 may include at least one of silicon oxide (SiOₓ), silicon nitride (SiNₓ), silicon oxynitride (SiOₓN_{y}), aluminum oxide (Al₂O₃), aluminum nitride (AlN), and another inorganic insulating material, or an organic insulating material such as an acrylic resin, an epoxy resin, a phenolic resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, a polymethyl methacrylate-polycarbonate synthetic resin, or another organic insulating material.

In one embodiment, the display device DD may further include the bank BNK located around the emission area EA. In one embodiment, the bank BNK may be disposed between the fifth insulating layer 17 and the seventh insulating layer 22. For example, the bank BNK may be disposed on the fifth insulating layer 17, and may be covered by the seventh insulating layer 22. The location of the bank BNK may vary depending on embodiments.

In one embodiment, the bank BNK may include at least one organic insulating layer. In one embodiment, the bank BNK may include an inclined surface that is inclined at a constant angle or has a gently curved shape. At least a part of the light emitted from the light-emitting elements ED may travel toward the inclined side surface of the bank BNK.

In one embodiment, the display device DD may further include a reflective pattern layer disposed on the bank BNK. For example, the display device DD may include a reflective pattern layer disposed on a side surface and/or a top surface of the bank BNK. A reflective partition wall may be formed at the outside of each emission area EA by the bank BNK and the reflective pattern layer. Accordingly, the light emission efficiency of the pixels PX may be increased.

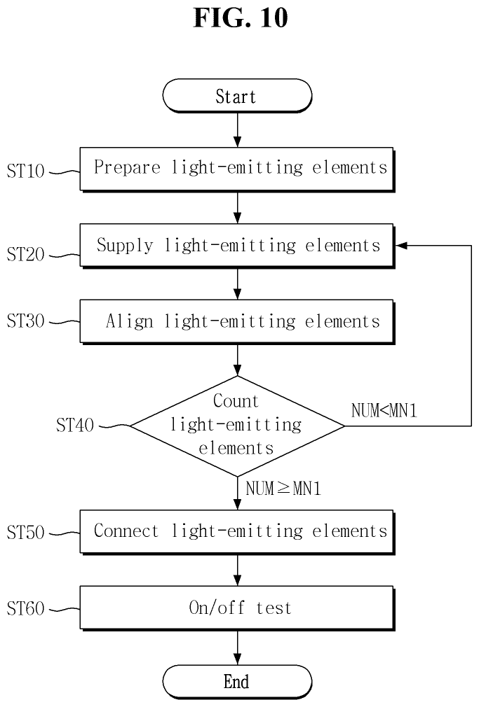

FIG. 10 is a flowchart illustrating a method of manufacturing the display device DD according to one embodiment. For example, FIG. 10 shows, in the manufacturing steps of the pixels PX, manufacturing steps for disposing the light-emitting elements ED in the pixel areas PXA (for example, the emission areas EA surrounded by the bank BNK, or the light-emitting element arrangement areas corresponding to the arrays ARR disposed in the emission areas EA) of the display device DD according to one embodiment.

Referring to FIGS. 1 to 10, first, light-emitting elements ED may be prepared. For example, light-emitting elements ED including semiconductor layers grown and etched on a semiconductor substrate may be formed or prepared. In one embodiment, the light-emitting elements ED may be prepared while being dispersed in an ink. For example, the step of preparing the light-emitting elements ED may include a step of preparing a light-emitting element ink including the light-emitting elements ED. For example, the light-emitting element ink in which the light-emitting elements ED are dispersed in an ink having fluidity may be prepared (step ST10).

Thereafter, the light-emitting elements ED may be supplied to the emission areas EA (or the arrays ARR disposed in the emission areas EA) of the pixels PX. In one embodiment, the step of supplying the light-emitting elements ED to the emission areas EA may include a step of supplying the light-emitting element ink to the emission areas EA by an inkjet printing method. For example, the light-emitting elements ED may be supplied to the emission areas EA by dropping the light-emitting element ink including the light-emitting elements ED to the emission areas EA by an inkjet printing method (step ST20).

Thereafter, the light-emitting elements ED supplied to the emission areas EA may be aligned. For example, by applying an alignment signal to the alignment electrodes ALE disposed in the emission areas EA, the light-emitting elements ED may be distributed and/or aligned in the emission areas EA of the pixels PX or the arrays ARR included in the emission areas EA (step ST30).

Thereafter, the light-emitting elements ED aligned in the emission areas EA may be counted. For example, the number of light-emitting elements ED appropriately disposed or aligned in the emission areas EA of the pixels PX or the arrays ARR included in the emission areas ARR may be counted (step ST40).

In embodiments, after the number of light-emitting elements ED is counted, the light-emitting elements ED may be additionally supplied to at least one array ARR in which the light-emitting elements ED of which number is less than a reference number MN1 are disposed among the arrays ARR of the pixels PX. For example, in case that the number of light-emitting elements ED aligned in at least one emission area EA or at least one array ARR is less than the reference number MN1, the steps of supplying the light-emitting elements ED to the corresponding emission area EA or array ARR, aligning light-emitting elements ED, and counting the number of light-emitting elements ED may be sequentially performed again. For example, until the number of light-emitting elements ED aligned in each emission area EA or each array ARR (for example, aligned to be connected in parallel to each other) is greater than or equal to the reference number MN1, the light-emitting elements ED may be additionally supplied to and aligned in at least one emission area EA or array ARR in which the light-emitting elements ED of which number is less than the reference number MN1 are disposed. In case that the number NUM of light-emitting elements ED aligned in each emission area EA or each array ARR is greater than or equal to the reference number MN1, the steps of supplying the light-emitting elements ED to the corresponding emission area EA or array ARR, aligning them, and counting the number of them may be completed.

In one embodiment, the reference number MN1 may be a value that allows a current value flowing through each light-emitting element ED to be lowered to secure the reliability of each light-emitting element ED. For example, in case that a single light-emitting element ED is disposed in each array ARR, the reference number MN1 may be a value that allows the maximum value of current flowing through each light-emitting element ED to be lower than the maximum value of current flowing through a single light-emitting element ED. For example, in case that a single light-emitting element ED is disposed in each array ARR, if the data signal corresponding to the highest grayscale flows through the pixel PX, the driving current corresponding to the highest grayscale may flow through the single light-emitting element ED. On the other hand, in case that two or more light-emitting elements ED are disposed in each array ARR and connected in parallel to each other, even if the driving current corresponding to the highest grayscale flows through the pixel PX, the driving current may be distributed and flow through the two or more light-emitting elements ED and, thus, deterioration of the light-emitting elements ED may be mitigated or reduced.

Accordingly, the reference number MN1 may be set to greater than or equal to two. For example, two or more light-emitting elements ED may be appropriately disposed or aligned in each array ARR.

In one embodiment, even in an embodiment in which each of the pixels PX includes at least two arrays ARR, the number of light-emitting elements ED disposed in each of the at least two arrays ARR may be greater than or equal to two. For example, in an embodiment in which four arrays ARR are disposed in the emission area EA of each pixel PX, at least two light-emitting elements ED may be appropriately disposed or aligned in each array ARR, so that eight or more light-emitting elements ED may be appropriately disposed or aligned in the emission area EA of each pixel PX. The reference number MN1 may vary depending on the sizes of the emission areas EA and the number of the light-emitting elements ED, the deterioration characteristics of the light-emitting elements ED, or a target reliability value or luminance.

Thereafter, the light-emitting elements ED aligned in the emission areas EA (or the arrays ARR) may be connected. For example, by forming the pixel electrodes ELT including the first pixel electrode ELT1 and the second pixel electrode ELT2 on ends of the light-emitting elements ED, the light-emitting elements ED may be connected between the first pixel electrode ELT1 and the second pixel electrode ELT2 of each of the pixels PX. For example, by forming a pair of pixel electrodes ELT in each array ARR, the light-emitting elements ED aligned in the corresponding array ARR may be connected to each other in parallel. Accordingly, the light-emitting elements ED may be appropriately disposed in the emission areas EA, and an electrical signal may be applied to the light-emitting elements ED. In one embodiment, by forming the pixel electrodes ELT after the light-emitting elements ED of which number is greater than or equal to the reference number MN1 are aligned in the respective emission areas EA or the respective arrays ARR, the manufacturing efficiency of the display device DD may be increased, and the yield may be improved (step ST50).

In one embodiment, after the light-emitting elements ED are disposed in the emission areas EA, an on/off test for the pixels PX may be performed. In one embodiment, the on/off test may include a step of applying an electrical signal to the light-emitting elements ED and counting the number of light-emitting elements ED that emit light in response thereto. Further, the on/off test may include a step of determining whether or not the pixels PX and the display device DD including the pixels PX are defective based on the number or luminance of the light-emitting elements ED disposed in the pixels PX. The light-emitting elements ED appropriately aligned and connected to each emission area EA (or each array ARR) may include effective light-emitting elements that may be turned on (step ST60).

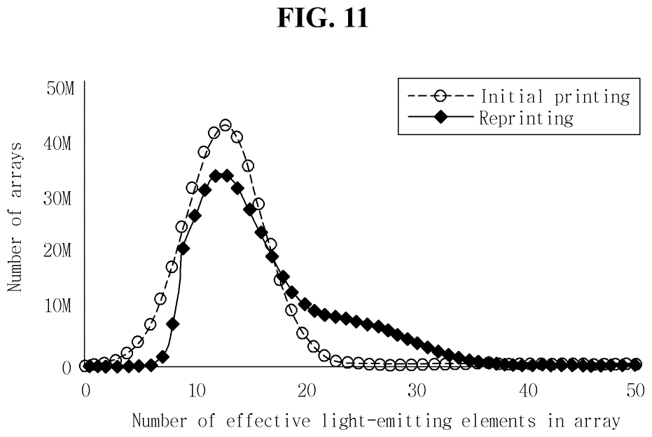

FIG. 11 is a graph showing distribution of the light-emitting elements ED according to one embodiment. For example, FIG. 11 shows distribution of the number of effective light-emitting elements ED disposed in each array ARR according to one embodiment. In the specification, the effective light-emitting elements ED may be light-emitting elements ED that is appropriately aligned and/or connected in each array ARR or each emission area EA.

Referring to FIGS. 1 to 11, in case that the light-emitting elements ED are supplied to and aligned in the arrays ARR by a printing method (for example, an inkjet printing method), the light-emitting elements ED may be additionally supplied to and aligned in at least some of the arrays ARR, so that the distribution pattern of the light-emitting elements ED (for example, the effective light-emitting elements ED) supplied to and aligned in the entire arrays ARR may change.

For example, a sufficiently large number of emission areas EA and arrays ARR may be disposed in the display area DPA, and the distribution of the number of effective light-emitting elements ED by an initial printing in which the light-emitting elements ED are supplied to the entire arrays ARR once by the inkjet printing method may follow normal distribution or Poisson distribution.

In case that the light-emitting elements ED is supplied to the respective arrays ARR disposed in the display area DPA and the emission areas EA including the light-emitting elements ED by performing an initial printing once using a printing method, a probability P_{ED} that the light-emitting elements ED exist in the light-emitting element ink containing a solvent and the light-emitting elements ED may be expressed by Equation 1 below:

$${P}_{ED} = \frac{{V}_{EDs}}{{V}_{EDs} + {V}_{solvent}} \qquad [ Equation 1 ]$$

In Equation 1, P_{ED} may be based on the amount of one drop of light-emitting element ink, e.g., the probability that the light-emitting elements ED exist in one drop of the light-emitting element ink supplied to each emission area EA or each array ARR. Further, V_{EDs} may be a volume of the light-emitting elements ED included in one drop of the light-emitting element ink, and Vₛₒₗᵥₑₙₜ may be a volume of the solvent included in one drop of the light-emitting element ink.

A probability f(k) that k light-emitting elements ED are supplied to and aligned in each array ARR and/or each emission area EA by one drop of the light-emitting element ink may be expressed by Equation 2 below:

$$f ( k ) = {nC}_{k} {{P}_{ED}^{k} ( 1 - {P}_{ED} )}^{n - k} \qquad [ Equation 2 ]$$

In Equation 2, nCₖ may be a binomial coefficient, where n may be a number of unit volumes obtained by dividing the volume of the light-emitting element ink by the volume of one light-emitting element ED, and Cₖ may be a number of cases (for example, combinations) of selecting k out of n, which is the number of unit volumes.

In case that the light-emitting elements ED is supplied to the arrays ARR disposed in the display area DPA and the emission areas EA including the light-emitting elements ED by performing an initial printing once, the distribution of the number of light-emitting elements ED disposed in the respective arrays ARR of the display area DPA may follow a normal distribution according to the initial printing indicated by a dotted line of FIG. 11. An average value μ and a standard deviation σ, which are parameters of the normal distribution, may be expressed by Equation 3 and Equation 4:

$$μ = {nP}_{ED} \qquad [ Equation 3 ]$$

$$σ = \sqrt{{nP}_{ED} ( 1 - {P}_{ED} )} \qquad [ Equation 4 ]$$

However, in an embodiment, the light-emitting elements ED may be additionally supplied and aligned by performing reprinting in the emission areas EA or the arrays ARR in case that the number of effective light-emitting elements ED supplied and aligned by initial printing is less than the reference number MN1. Accordingly, the distribution of the number of effective light-emitting elements ED supplied to and aligned in the arrays ARR of the display area DPA by performing reprinting at least once may not follow the above-described normal distribution or Poisson distribution.

For example, in an embodiment, the distribution of the number of light-emitting elements ED (for example, the effective light-emitting elements ED appropriately arranged or connected between the first pixel electrode ELT1 and the second pixel electrode ELT2) included in the pixels PX may be asymmetric abnormal distribution. For example, the distribution of the number of arrays ARR in relation to the number of effective light-emitting elements ED disposed in each of the arrays ARR of the display area DPA after the reprinting is performed at least once may have an asymmetric shape with respect to the mode.

Further, depending on embodiments, the number of light-emitting elements ED (for example, the effective light-emitting elements ED) disposed in each of the arrays ARR or each of the emission areas EA of the pixels PX may be greater than the minimum number of light-emitting elements ED (for example, the effective light-emitting elements ED) that may be disposed in each of the arrays ARR or each of the emission areas EA according to the normal distribution or the Poisson distribution. In one embodiment, the number of light-emitting elements ED disposed in each emission area EA or each array ARR may be two or more, and may be changed or optimized depending on the size of each of the emission area EA, the array ARR, or the light-emitting element ED.

For example, the minimum number (for example, the reference number MN1) of the light-emitting elements ED (for example, the effective light-emitting elements ED) supplied to and aligned in each array ARR by performing reprinting in at least one array ARR may be greater than the minimum number of light-emitting elements ED (for example, the effective light-emitting elements ED) supplied to and aligned in each array ARR by an initial printing. For example, the minimum number of effective light-emitting elements ED supplied to and aligned in each array ARR by an initial printing may be zero or one, and the minimum number of effective light-emitting elements ED supplied to and aligned in each array ARR by an initial printing and a reprinting may be two or more.

The graph of FIG. 11 shows the number of effective light-emitting elements ED disposed in more than 10000 arrays ARR included in an 8K resolution display device DD where each of the pixels PX includes four arrays ARR. In FIG. 11, the number of arrays ARR is expressed in million (M) units. For example, 10M arrays ARR may be 10 million arrays ARR.

In one embodiment, in the entire arrays ARR disposed in the display area DPA, the number of light-emitting elements ED disposed in the entire arrays ARR may be greater than the minimum number of light-emitting elements ED with the normal distribution or the Poisson distribution disposed in each of the entire arrays ARR by performing printing once. For example, the number of light-emitting elements ED disposed in each of the entire arrays ARR may be greater than or equal to two.

In another embodiment, only in some of the arrays ARR of the display area DPA, the minimum number of light-emitting elements ED disposed in the some arrays ARR may be increased so that the number of light-emitting elements ED disposed in the some arrays ARR does not follow the normal distribution or the Poisson distribution. For example, only in the arrays ARR disposed in the pixels PX of some pixel groups among the pixel groups including the first pixels PX1, the second pixels PX2, the third pixels PX3, and/or the fourth pixels PX4, the minimum number of light-emitting elements ED disposed in each of the arrays ARR may be controlled to be greater than or equal to two. In one embodiment, depending on types or deterioration characteristics of the pixels PX or the light-emitting elements ED disposed in the pixels PX, pixels PX that are controlled such that the maximum number of light-emitting elements ED disposed in each of the arrays ARR is greater than or equal to two may be selected. For example, only in the arrays ARR disposed in the pixels PX (for example, red pixels, or red and blue pixels) in which a relatively large decrease in luminance occurs due to deterioration, the minimum number of light-emitting elements ED disposed in each of the arrays ARR may be controlled to be greater than or equal to two.

In one embodiment, the maximum number of light-emitting elements ED disposed in the emission area EA of each pixel PX may vary depending on the sizes of the pixels PX and/or the light-emitting elements ED. For example, the maximum number of light-emitting elements ED disposed in each emission area EA may vary depending on the size of the emission area EA, the number of arrays ARR disposed in the emission area EA, the size of each array ARR, and/or the size of the light-emitting elements ED. For example, in a 65-inch 8K resolution display device DD in which each light-emitting element ED has a length of approximately 4 μm and each pixel PX includes four arrays ARR, the number of light-emitting elements ED disposed in each emission area EA may be limited to less than or equal to 200. Accordingly, the clumpiness of the light-emitting elements ED may be reduced, and the light-emitting elements ED may be efficiently arranged in each emission area EA.

In accordance with embodiments, as the minimum number of light-emitting elements ED disposed in each array ARR is greater than the minimum number according to the normal distribution or the Poisson distribution, the driving current flowing through each light-emitting element ED may be decreased. Accordingly, the stress applied to each light-emitting element ED may be alleviated or reduced, and the deterioration of the light-emitting elements ED may be mitigated or reduced.

In one embodiment, the light-emitting elements ED may be ultra-small light-emitting diodes (for example, micro LEDs or nano LEDs) having a width and a length less than or equal to about 100 μm. Since the size of the light-emitting elements ED decreases, a ratio of a surface area to a volume of each light-emitting element ED may increase. Accordingly, the ultra-small light-emitting diodes may have a non-emission recombination rate higher than a non-emission recombination rate of light-emitting diodes having a larger size, so that the luminous efficiency of the ultra-small light-emitting diodes may be reduced. However, in embodiments, the deterioration of the light-emitting elements ED may be mitigated or reduced by increasing the minimum number of light-emitting elements ED disposed in each array ARR. Accordingly, even in case that the light-emitting elements ED are ultra-small light-emitting diodes, the luminous efficiency and the deterioration characteristics of the light-emitting elements ED and the pixels PX including the light-emitting elements ED may be improved.

In one embodiment, in the arrays ARR or the emission areas EA to which the light-emitting elements ED are additionally supplied by performing reprinting at least once, structural or optical characteristics that may distinguish at least two groups of sequentially supplied light-emitting elements ED may be exhibited. For example, due to a binder included in the light-emitting element ink, the boundary between a first group of light-emitting elements ED supplied and aligned first and a second group of light-emitting elements ED supplied and aligned later may be visually recognized, or an optical interface where optical characteristics related to a refractive index or a reflectivity change may occur. For example, the types, sizes, or shapes of the first group of light-emitting elements ED and the second group of light-emitting elements ED may be different.

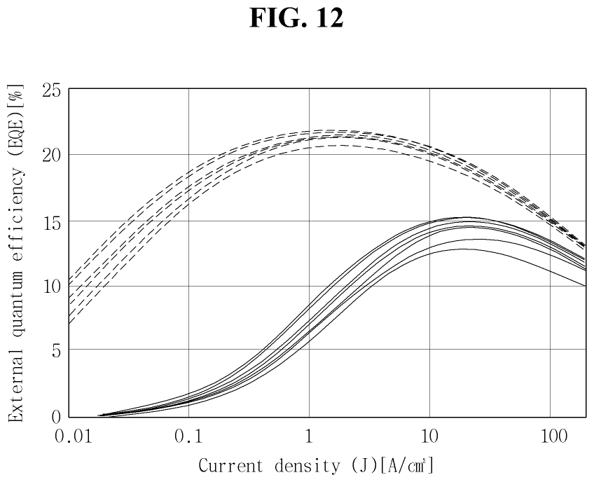

FIG. 12 is a graph showing changes in efficiency due to deterioration of the light-emitting elements ED. For example, FIG. 12 shows changes in external quantum efficiency (EQE) of the light-emitting elements ED according to a current density (J) flowing through the light-emitting elements ED (for example, ten light-emitting elements ED) selected as samples.

Referring to FIG. 12, an initial external quantum efficiency of the light-emitting elements ED may be relatively high as shown in the graph indicated by a dotted line. If the light-emitting elements ED are made to continuously emit light by supplying a driving current to the light-emitting elements ED, the light-emitting elements ED may deteriorate and the luminous efficiency of the light-emitting elements ED may be reduced. For example, if the light-emitting elements ED are made to emit light for 500 hours by supplying a driving current to each of the light-emitting elements ED, the external quantum efficiency of the light-emitting elements ED may be decreased as in the graph indicated by a solid line. Accordingly, even if the same driving current is supplied, the luminance of the light-emitting elements ED may be decreased.

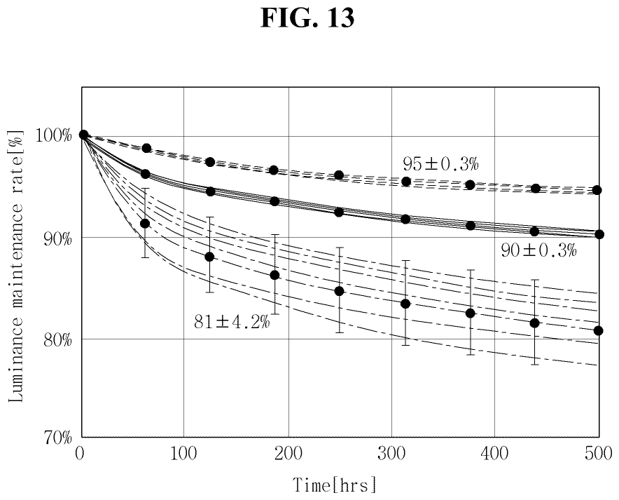

FIG. 13 is a graph showing changes in luminance maintenance rate due to the deterioration of the light-emitting elements ED. For example, FIG. 13 shows changes in luminance maintenance rate of the light-emitting elements ED with respect to time (for example, emission time) in the case where the light-emitting elements ED selected as samples are divided into three groups and made to emit light by supplying a driving current of 50 A/cm² to different groups.

Referring to FIGS. 12 and 13, the luminance maintenance rate of the light-emitting elements ED that are made to emit light for 500 hours by supplying a first driving current of a high level (for example, a driving current of 50 A/cm²) may be decreased to about 81% on average compared to the initial luminance, and the range of deviation may be approximately ±4.2%. The reliability of the light-emitting elements ED driven by the first driving current for 500 hours may be approximately 81±4.2%.

The luminance maintenance rate of the light-emitting elements ED that are made to emit light for 500 hours by supplying a second driving current of an intermediate level (for example, a driving current of 25 A/cm²) may be decreased to about 90% on average compared to the initial luminance, and the range of deviation may be approximately ±0.3%. The reliability of the light-emitting elements ED driven by the second driving current for 500 hours may be approximately 90±0.3%.

The luminance maintenance rate of the light-emitting elements ED that are made to emit light for 500 hours by supplying a third driving current of a low level (for example, a driving current of 12 A/cm²) may be decreased to about 95% on average compared to the initial luminance, and the range of deviation may be approximately ±0.3%. The reliability of the light-emitting elements ED driven by the third driving current for 500 hours may be approximately 95±0.3%.

As described above, the changes in characteristics (for example, the changes in the external quantum efficiency or the luminance) due to the deterioration of the light-emitting elements ED may vary depending on the driving current flowing through each of the light-emitting elements ED. For example, as the driving current supplied to the light-emitting elements ED increases, the deterioration of the light-emitting elements ED may be accelerated and the reliability of the light-emitting elements ED may decrease. Accordingly, the reliability of the light-emitting elements ED may further decrease.

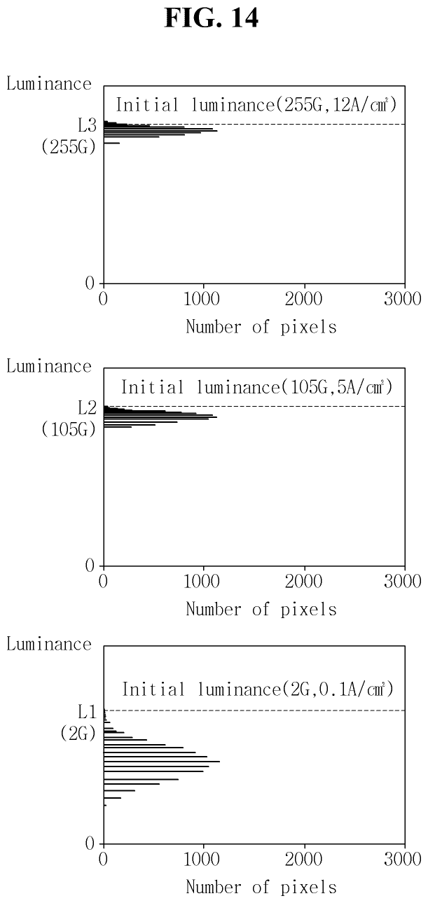

FIGS. 14 to 16 are graphs showing changes in luminance for each grayscale of the pixels PX including the light-emitting elements ED having different reliabilities.

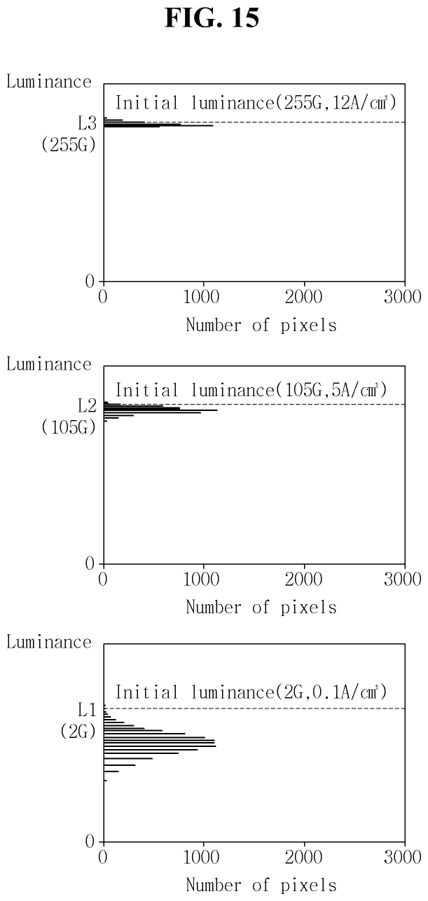

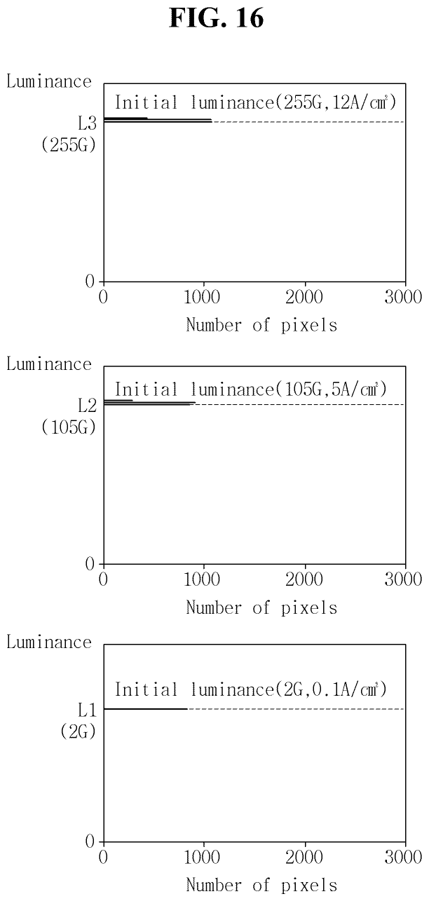

For example, FIG. 14 is the graph showing changes in luminance for each grayscale of the pixels PX including a relatively small number of light-emitting elements ED to which a driving current of a relatively high level (for example, the first driving current) is applied. FIG. 15 is the graph showing changes in luminance for each grayscale of the pixels PX including an intermediate number of light-emitting elements ED to which a driving current of an intermediate level (for example, the second driving current) is applied. FIG. 16 is the graph showing changes in luminance for each grayscale of the pixels PX including a relatively large number of light-emitting elements ED to which a driving current of a relatively low level (for example, the third driving current) is applied. In FIGS. 14 to 16, the dotted lines indicate the initial luminance for each reference grayscale, and the solid lines indicate the luminance that has been decreased due to the deterioration of the light-emitting elements ED and the pixels PX including the same.

Referring to FIG. 14, the pixels PX including the light-emitting elements ED (for example, the light-emitting elements ED that are driven by the first driving current for 500 hours to have a reliability of 81±4.2%) deteriorated by the driving current of a relatively high level may emit light with a luminance that has been decreased by a relatively large magnitude compared to the initial luminance (for example, a first luminance L1 corresponding to a 2 grayscale (2G) in which a driving current of 0.1 A/cm² is supplied to each pixel PX, a second luminance L2 corresponding to a 105 grayscale (105G) in which a driving current of 5 A/cm² is supplied to each pixel PX, and a third luminance L3 corresponding to a 255 grayscale (255G) in which a driving current of 12 A/cm² is supplied to each pixel PX) for the reference grayscales (for example, the 2 grayscale (2G), the 105 grayscale (105G), and the 255 grayscale (255G)). Further, the pixels PX may have a larger range of luminance variation compared to the pixels PX including the light-emitting elements ED deteriorated by the driving current of a lower level.

Referring to FIG. 15, the pixels PX including the light-emitting elements ED (for example, the light-emitting elements ED that are driven by the second driving current for 500 hours to have a reliability of 90±0.3%) deteriorated by the driving current of an intermediate level may emit light with a luminance that has been decreased compared to the initial luminance (for example, the first luminance L1, the second luminance L2, and the third luminance L3) for the reference grayscales (for example, the 2 grayscale (2G), the 105 grayscale (105G), and the 255 grayscale (255G)). However, a degree of luminance decrease or luminance variation of the pixels PX may be smaller than a degree of luminance decrease or luminance variation of the pixels PX including the light-emitting elements ED deteriorated by the driving current of a higher level.

Referring to FIG. 16, the pixels PX including the light-emitting elements ED (for example, the light-emitting elements ED that are driven by the third driving current for 500 hours to have a reliability of 95±0.3%) to which the driving current of a relatively low level is applied may emit light with a luminance that is substantially the same as the initial luminance (for example, the first luminance L1, the second luminance L2, and the third luminance L3) for the reference grayscales (for example, the 2 grayscale (2G), the 105 grayscale (105G), and the 255 grayscale (255G)). For example, the pixels PX including the light-emitting elements ED driven by the driving current of a relatively low level may substantially maintain the initial luminance.

As described above, in the case of pixels PX that include a smaller number of light-emitting elements ED and thus have a relatively low reliability, a degree of luminance change (for example, luminance decrease) of the pixels PX for the initial luminance may be large. On the other hand, in the case of pixels PX that include a larger number of light-emitting elements ED and thus have a high reliability, a degree of luminance change (for example, luminance decrease) of the pixels PX for the initial luminance may be small.

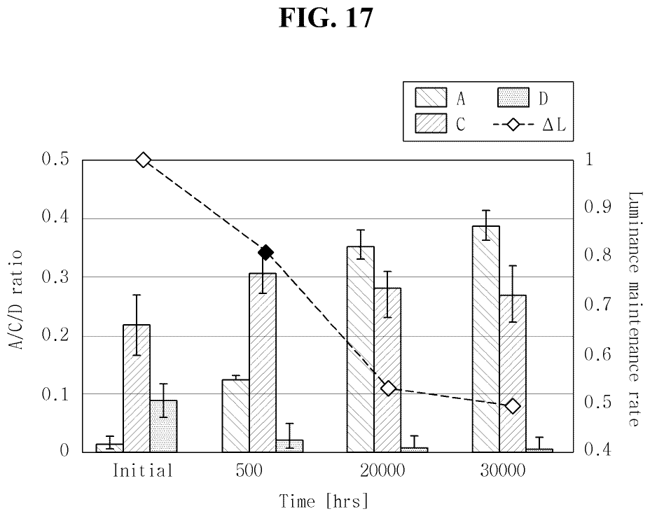

FIGS. 17 to 19 are graphs showing changes in ratio of non-emission recombination coefficients and changes in luminance maintenance rate of the light-emitting elements ED having different reliabilities with respect to time.

For example, FIGS. 17 to 19 show the changes in the luminance maintenance rate of the light-emitting element ED and the changes in A, C, and D coefficients corresponding to the non-emission recombination coefficients of electrons and holes in an ABCD model for modeling the deterioration characteristics related to the luminous efficiency of the light-emitting element ED. In FIGS. 17 to 19, the ratio of the recombination into photon (B) among the coefficients of the ABCD model is not illustrated.

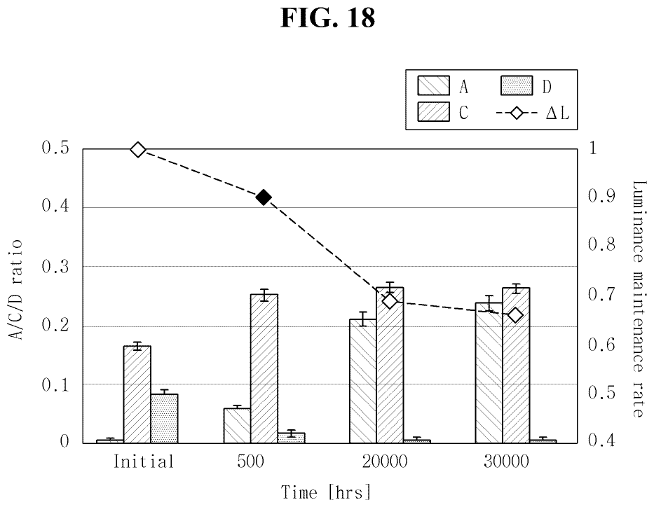

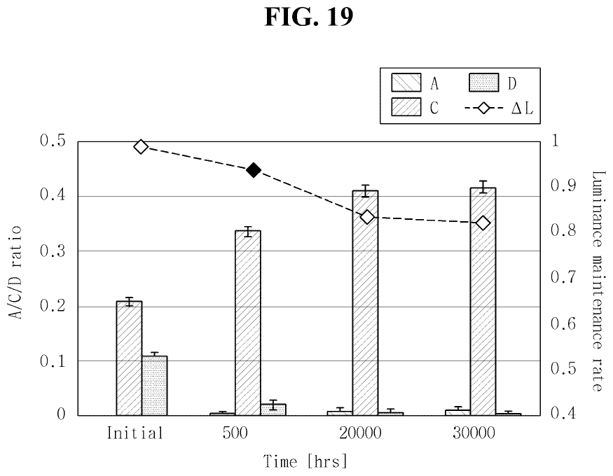

FIG. 17 shows the changes in the ratio of the non-emission recombination coefficients A, C, and D and the luminance maintenance rate of the light-emitting element ED having the reliability of approximately 81±4.2% at 500 hours with respect to time. FIG. 18 shows the changes in the ratio of the non-emission recombination coefficients A, C, and D and the luminance maintenance rate of the light-emitting element ED having the reliability of approximately 90±0.3% at 500 hours with respect to time. FIG. 19 shows the changes in the ratio of the non-emission recombination coefficients A, C, and D and the luminance maintenance rate of the light-emitting element ED having the reliability of approximately 95±0.3% at 500 hours with respect to time.

In FIGS. 17 to 19, the A coefficient indicates the Shockley-Read-Hall (SRH) recombination coefficient (or the non-emission recombination constant due to defects), and the C coefficient indicates the Auger recombination coefficient (or Auger constant). The D coefficient may indicate a defect assisted Shockley-Read-Hall recombination coefficient. In FIGS. 17 to 19, the dotted line indicated by ΔL shows the changes in the luminance maintenance rate of the light-emitting elements ED with respect to time.

Referring to FIGS. 17 to 19, in the light-emitting element ED having a lower reliability, the ratio of the A coefficient increases as the light-emitting element ED deteriorates, and the luminance maintenance rate of the light-emitting element ED may be decreased by a relatively large magnitude. On the other hand, in the light-emitting element ED having a higher reliability, the ratio of the C coefficient increases as the light-emitting element ED deteriorates, and the light-emitting element ED may have a high luminance maintenance rate. For example, the light-emitting element ED having a reliability of approximately 95±0.3% at 500 hours may maintain the luminance of approximately 80% or more even if it is driven for more than 30000 hours.

In the case of the display device DD in which two or more light-emitting elements ED are disposed in each array ARR according to the embodiments described above, the driving current flowing through each light-emitting element ED may be reduced, so that the deterioration of the light-emitting element ED may be mitigated. Accordingly, as the usage time (for example, the emission time) of the light-emitting elements ED of the display device DD according to embodiments increases, the Auger recombination coefficient among the non-emission recombination coefficients of the light-emitting elements ED tends to increase, and a high luminance maintenance rate may be exhibited. Accordingly, the deterioration of the pixels PX including the light-emitting elements ED and the display device DD including the pixels PX may be mitigated, and the reliability may be improved.

As described above, each of the pixels PX of the display device DD according to embodiments may include at least one array ARR disposed in the emission area EA. Further, at least two light-emitting elements ED arranged or connected in parallel to each other may be disposed in each array ARR. In embodiments, the distribution of the number of light-emitting elements ED (for example, the effective light-emitting elements) appropriately connected or aligned in each of the pixels PX (or the arrays ARR of the pixels PX) may not follow the normal distribution or the Poisson distribution. For example, the distribution of the number of light-emitting elements ED appropriately connected or aligned in each of the arrays ARR or each of the emission areas EA of the pixels PX may be abnormal distribution different from the normal distribution or the Poisson distribution. Further, the minimum number of light-emitting elements ED appropriately connected or aligned in each of the emission areas EA or each of the arrays ARR may be greater than the minimum number of light-emitting elements ED disposed in each of the arrays ARR or each of the emission areas EA according to the normal distribution or the Poisson distribution. In one embodiment, after the step of supplying and aligning the light-emitting elements ED is completed at least once, the number of light-emitting elements ED disposed in each array ARR may be counted, and the light-emitting elements ED may be additionally supplied to the array ARR in which the light-emitting elements ED of which number is less than the reference number MN1 are disposed or aligned.

In accordance with the display device DD and the method of manufacturing the same according to embodiments, the light-emitting elements ED of which number is greater than or equal to the reference number MN1 (for example, two or more) may be disposed in each array ARR. Accordingly, the current flowing through each of the light-emitting elements ED may be reduced, and the deterioration of the pixels PX may be reduced. Further, it is possible to prevent image quality deterioration (for example, afterimage such as image-sticking) of the display device DD that may occur due to deterioration of the pixels PX.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
pixels comprising light-emitting elements disposed in each emission area, wherein
each of the pixels comprises at least one array comprising the light-emitting elements and disposed in the emission area, and
a number of the light-emitting elements disposed in each of arrays of the pixels is greater than a minimum number of the light-emitting elements in the each of the arrays according to normal distribution or Poisson distribution.

2. The display device of claim 1, wherein the number of the light-emitting elements disposed in the each of the arrays of the pixels is greater than or equal to two.

3. The display device of claim 1, wherein the light-emitting elements disposed in the each of the arrays of the pixels are connected in parallel to each other.

4. The display device of claim 1, further comprising:
a display area where the pixels are disposed,
wherein the number of the light-emitting elements disposed in each of entire arrays of the pixels in the display area is greater than the minimum number of the light-emitting elements according to the normal distribution or Poisson distribution disposed in the each of the entire arrays.

5. The display device of claim 4, wherein the number of the light-emitting elements disposed in each of the entire arrays is greater than or equal to two.

6. The display device of claim 1, wherein a distribution of the number of the light-emitting elements disposed in the each of the arrays of the pixels has an asymmetric shape with respect to a mode.

7. The display device of claim 1, wherein the each of the pixels further comprises a first pixel electrode electrically connected to ends of the light-emitting elements, and a second pixel electrode electrically connected to another ends of the light-emitting elements.

8. The display device of claim 7, wherein the light-emitting elements of the each of the pixels comprise effective light-emitting elements connected between the first pixel electrode and the second pixel electrode.

9. The display device of claim 1, wherein
the each of the pixels comprises at least two arrays, and
the number of the light-emitting elements disposed in each of the at least two arrays is greater than or equal to two.

10. The display device of claim 1, wherein each of a width and a length of the light-emitting elements is less than or equal to about 100 μm.

11. The display device of claim 1, wherein
the each of the pixels further comprises at least one pair of alignment electrodes disposed adjacent to the light-emitting elements, and
the light-emitting elements of the each of the pixels are arranged between the at least one pair of alignment electrodes.

12. A method of manufacturing a display device, comprising:
preparing light-emitting elements;
supplying the light-emitting elements to emission areas of pixels;
aligning the light-emitting elements in arrays disposed in the emission areas;
counting the light-emitting elements disposed in each of the arrays; and
connecting the light-emitting elements between a first pixel electrode and a second pixel electrode of each of the pixels,
wherein after the counting of the light-emitting elements, the light-emitting elements are additionally supplied to at least one array supplied with a number of the light-emitting elements less than a reference number, among the arrays.

13. The method of claim 12, wherein in case that the number of the light-emitting elements disposed in the at least one array among the arrays is less than the reference number, the light-emitting elements are additionally supplied to and aligned in the at least one array until the number of the light-emitting elements disposed in the at least one array is greater than or equal to the reference number.

14. The method of claim 12, wherein the reference number is greater than or equal to two.

15. The method of claim 12, wherein the preparing of the light-emitting elements comprises preparing a light-emitting element ink including the light-emitting elements.

16. The method of claim 15, wherein the supplying of the light-emitting elements to the emission areas comprises supplying the light-emitting element ink to the emission areas by an inkjet printing method.

17. The method of claim 12, wherein the aligning of the light-emitting elements in the arrays comprises applying an alignment signal to alignment electrodes disposed in the emission areas.

18. The method of claim 12, wherein the connecting of the light-emitting elements between the first pixel electrode and the second pixel electrode of the each of the pixels comprises forming a plurality of pixel electrodes comprising the first pixel electrode and the second pixel electrode on ends of the light-emitting elements.

19. The method of claim 12, wherein the connecting of the light-emitting elements between the first pixel electrode and the second pixel electrode of the each of the pixels comprises connecting the light-emitting elements disposed in the each of the arrays in parallel.

20. An electronic device for providing an image, comprising:
a display device comprising pixels, the pixels comprising light-emitting elements disposed in each emission area, wherein
each of the pixels comprises at least one array comprising the light-emitting elements and disposed in the emission area, and
a number of the light-emitting elements disposed in each of arrays of the pixels is greater than a minimum number of the light-emitting elements in the each of the arrays according to normal distribution or Poisson distribution.
